(19) United States
(12) Patent Application Publication
(10) Pub. No.: US 2025/0062243 A1
(43) Pub. Date: Feb. 20, 2025

(54) HIGH-FREQUENCY HIGH-POWER DENSITY MODULE POWER SUPPLY, PARALLEL COMBINATION, MANUFACTURING METHOD, AND FLEXIBLE AND RIGID COMBINATION ASSEMBLY

(71) Applicant: SHANGHAI METAPWR ELECTRONICS CO., LTD, Shanghai (CN)

(72) Inventor: Jianhong ZENG, Shanghai (CN)

(73) Assignee: SHANGHAI METAPWR ELECTRONICS CO., LTD, Shanghai (CN)

(21) Appl. No.: 18/937,034

(22) Filed: Nov. 5, 2024

Related U.S. Application Data
(63) Continuation of application No. PCT/CN2023/090989, filed on Apr. 26, 2023.

(30) Foreign Application Priority Data
May 5, 2022 (CN) 202210483027.5

(51) Int. Cl. H01L 23/538; H01L 21/48; H01L 23/367; H01L 23/66; H01L 25/16

(52) U.S. Cl. CPC H01L 23/5387; H01L 21/4853; H01L 23/5385; H01L 23/66; H01L 25/162; H01L 23/3675; H01L 28/40; H01L 2223/6644

(57) ABSTRACT

A high-frequency high-power density module power supply including a carrier element is provided. At least one surface of the carrier element is provided with a surface power pin, and a flexible and rigid combination assembly. The flexible and rigid combination assembly comprises at least one rigid part and at least one flexible part, the at least one rigid part comprises a power semiconductor assembly, and the rigid part is electrically connected to the flexible part. At least one part of the flexible and rigid combination assembly is electrically connected to the surface power pin of the carrier element. The flexible and rigid combination assembly is bent by using the surface of the carrier element as a carrier. The rigid part and the flexible part are connected by means of the same flexible component.

### CROSS-REFERENCE TO RELATED APPLICATIONS

This application is a continuation of international application of PCT patent application PCT/CN2023/090989, filed on Apr. 26, 2023, which claims the priority benefit of China application no. 202210483027.5 filed on May 5, 2022. The entirety of the above-mentioned patent application is hereby incorporated by reference herein and made a part of this specification.

### TECHNICAL FIELD

The invention relates to a semiconductor package, in particular to a high-frequency high-power density module power supply, parallel combination, manufacturing method, and flexible and rigid combination assembly.

### DESCRIPTION OF RELATED ART

Along with the large increase of the data processing amount, more and more layers of the mainboard of the server are more and more precious, and the requirement for the occupied area of the power supply becomes higher and higher. Taking a large number of step-down circuits used by a server as an example, more and more schemes are adopted, and the occupied area is reduced by adopting a power supply module mode of stacking the power semiconductor elements and the magnetic elements. However, the semiconductor is placed under the inductor, and the semiconductor is used as a main heat source and is difficult to conduct the heat to the radiator. More and more schemes select to place the semiconductor on the inductor so as to facilitate the customer to install the radiator and improve the overall power. However, this may cause an increase in loss. Due to the defects in the prior art, the two advantages are difficult to obtain at the same time.

As shown in FIG. 1A, a power semiconductor element of the Buck circuit comprises two switching devices, a high-speed switching switch needs to place decoupling capacitors Cin1 nearby so as to suppress the decrease of reliability caused by voltage spikes. Due to the limitation of the height and the space of the module, the capacity of Cin1 is usually relatively small, for example, 1 uF, and is only used for reducing the loop inductance Lloop1, so that more capacitors Cin2 need to be placed for filtering at the position close to the pin of the module.

As shown in FIG. 1B, the conductive pin is fixed on the inductor, and then is combined with the power semiconductor element through IPM welding. Due to the existence of the height of the module, the loop of the Vin Pin and the GND Pin is large, and the LLoop2 is large and reaches up to 5 nH or above. Lloop2 resonates with Cin1, resulting in increased loss and even system instability.

As shown in FIG. 1C, some of the prior art preferably select to stack Vin Pin and GND Pin and reduce the path of Lloop2, and the parasitic parameter of Lloop2 can be reduced to 2 nH. However, implementation is very difficult. Due to the fact that the size of the module is small, the space reserved for the conductive pins is smaller, under the small size, pin stacking, bending, re-processing and the flatness of inductor pin are carried out, then IPM welding is achieved, the process is complex, and automation is difficult.

Therefore, how to greatly reduce the loss while ensuring the heat dissipation capability, ensure the stability of the system and save the module space, simplify the process, enable the high-frequency and high-power to be realized are urgent problems to be solved.

### SUMMARY

In view of this, one of the objectives of the present application is to provide a high-frequency high-power density module power supply comprises:

A carrier element, at least one surface of the carrier element having a surface power pin;

A flexible and rigid combination assembly, comprises at least one rigid part and at least one flexible part; the at least one rigid part comprises a power semiconductor assembly; the rigid part is electrically connected with the flexible part;

At least one of the flexible and rigid combination assembly is electrically connected to a surface power pin of the carrier element;

The flexible and rigid combination assembly is bent by using the surface of the carrier element as a carrier, and the bending position is the flexible part;

The rigid part and the flexible part are formed by interconnecting the same flexible component, and the at least one rigid part and/or the flexible component are provided with at least one power pin.

Preferably, the rigid part containing the power semiconductor assembly is arranged on the upper surface of the carrier element, and the upper surface of the carrier element is in power interconnection with the carrier element.

Preferably, the rigid part containing the power semiconductor assembly is arranged on the side surface of the carrier element, and power interconnection is carried out with the carrier element on the side surface of the carrier element.

Preferably, at least two rigid parts comprise power semiconductor components and are respectively arranged on two different side surfaces of the carrier element.

Preferably, the rigid part containing the power semiconductor assembly is arranged on the lower surface of the carrier element, and power interconnection is carried out with the carrier element on the lower surface of the carrier element.

Preferably, wherein the flexible component comprises at least one insulating layer and at least two conductive layers separated by the insulating layer, the flexible component comprises at least one overlapping region, and in the overlapping region, both sides of the insulating layer are provided with conductive layers, and the polarities of the electrodes of the conductive layer are opposite.

Preferably, wherein the flexible component is provided with at least one power pin, specifically, an end pin is arranged at the end of the flexible component, and the end pin comprises at least one power pin.

Preferably, the end pin is formed on one surface of the carrier element after being bent through the flexible component.

Preferably, a space for accommodating the end pin is formed in one surface of the carrier element.

Preferably, wherein the rigid part and/or the flexible part are provided with at least one power grounding pin, and the power pin and the power grounding pin are alternately arranged.

Preferably, a conductive layer arranged on one side, which is in the direction away from the carrier element, of the flexible component is an outer conductive layer, and other conductive layers not including the outer conductive layer are inner conductive layers;

The flexible component is provided with at least one power pin, and specifically, an end pin is arranged at the end of the flexible component, and the end pin comprises at least one power pin;

The inner conductive layer is electrically connected to at least one end pin by penetrating through the flexible component.

Preferably, wherein the rigid part and/or the flexible part are provided with at least one signal pin, and the signal pin and the power pin are respectively arranged on different surfaces of the carrier element.

Preferably, wherein the flexible component has a copper reduction structure or a copper removal structure to form a flexible part.

Preferably, the copper reduction structure is of a thinned structure or a stamp hole structure.

Preferably, the power semiconductor assembly comprises a power semiconductor element and a first plastic package body which are arranged on the upper surface of the flexible component, the power semiconductor element is electrically connected with the flexible component, and the first plastic package body wraps the power semiconductor element and at least one part of the upper surface of the flexible component.

Preferably, wherein the power semiconductor assembly comprises a first PCB board arranged on the upper surface of the flexible component, a power semiconductor element arranged on the first PCB board and a first plastic package body, the power semiconductor element is electrically connected with the flexible component through the first PCB board, and the first plastic package body wraps the first PCB board and the power semiconductor element.

Preferably, the power semiconductor assembly further comprises a second PCB arranged on the lower surface of the flexible part, and the first PCB is electrically connected with the second PCB through a via hole electrical connector arranged in the via hole.

Preferably, the power semiconductor assembly further comprises at least one embedded wafer, the embedded wafer is arranged in the first PCB and/or between the first PCB and the flexible component and/or the inner of the flexible PCB, and the embedded wafer is electrically connected with the first PCB and/or the flexible component.

Preferably, the rigid part comprises a side capacitor arranged on the flexible component.

Preferably, the rigid part further comprises a second plastic package body, and the second plastic package body wraps the side capacitor and at least part of the flexible component.

Preferably, an outer conductive layer on at least one side of the flexible component is provided with a first electrical area and a second electrical area which are opposite in electrical property, the second electrical area is electrically connected with the corresponding inner conductive layer, at least one side capacitor is arranged on the outer conductive layer, and two electrodes of the side capacitor are electrically connected with the first electrical area and the second electrical area respectively.

Preferably, the rigid part comprises a thickened metal block, and the thickened metal block is electrically connected with the flexible component.

Preferably, the circuit formed by the power semiconductor element comprises at least two switch bridge arms, and the high-frequency jump voltage ends of the switch bridge arms are electrically interconnected by means of electrical connectors provided on the surface of the carrier element.

Preferably, a circuit formed by the power semiconductor element comprises at least one switch bridge arm, and a direct-current voltage end of the switch bridge arm is electrically connected with the flexible component through an electrical connector arranged on the surface of the carrier element.

Preferably, at least one rigid part is a rigid capacitor assembly;

When the flexible component is assembled on the surface of the carrier element, the outer conductive layer on at least one side of the flexible component is provided with a first electrical area and a second electrical area which are opposite in electrical property, and the second electrical area is electrically connected with the inner conductive layer at the corresponding position;

The rigid capacitor assembly is arranged on the conductive layer on the outer side of the flexible component, the rigid capacitor assembly comprises a third plastic package body and at least one side capacitor, the two electrodes of the side capacitor are electrically connected with the first electrical area and the second electrical area respectively, and the third plastic package body wraps the side capacitor and at least one part of the conductive layer on the outer side of the flexible component.

Preferably, the bottom of the rigid capacitor assembly is flush with the bottom of the carrier element; and the at least one rigid part is provided with at least one power pin, specifically, the bottom of the rigid capacitor assembly is provided with at least one power pin through electroplating.

Preferably, the high-frequency high-power-density module power supply is characterized in that at least one rigid part is a rigid control assembly;

When the flexible component is assembled on the surface of the carrier element, the rigid control assembly is arranged on the conductive layer on the outer side of the flexible component on at least one side;

The rigid control assembly comprises a control chip and a fourth plastic package, the fourth plastic package covers the control chip and at least a part of the conductive layer outside the flexible component, and the control chip is used for providing a control signal to the power semiconductor component.

Preferably, the bottom of the rigid control assembly and the bottom of the rigid capacitor assembly are flush with the bottom of the carrier element, and at least one signal pin is arranged at the bottom of the rigid control assembly through electroplating; and the at least one rigid part is provided with at least one power pin, and specifically, the bottom of the rigid capacitor assembly is provided with at least one power pin through electroplating.

Preferably, the bottom of at least one rigid part is lower than the bottom of the carrier element, so that when the high-frequency high-power density module power supply is installed on the client mainboard, the space for accommodating the output decoupling capacitor is reserved below the carrier element.

Preferably, at least one rigid part is an output decoupling capacitor assembly, the output decoupling capacitor assembly is arranged at the bottom of the carrier element, the output decoupling capacitor assembly is used for containing an output decoupling capacitor, one electrode of the decoupling capacitor is electrically connected with the carrier element, and the other electrode is electrically connected with the flexible component.

Preferably, the high-frequency high-power-density module power supply further comprises a power supply flying wire, one end of the power supply flying wire is electrically connected with the flexible and rigid combination assembly, the other end of the power supply flying wire is used for being electrically connected with a client mainboard, and the power supply flying wire is used for supplying power to a high-frequency high-power density module power supply from the position away from the high-frequency high-power density module power supply.

A flexible and rigid combination assembly.

A high-frequency high-power-density module power supply:
At least one power semiconductor assembly, wherein the power semiconductor assembly comprises a power semiconductor element and a first plastic package body, and the first plastic package body wraps the power semiconductor element;
a carrier element arranged at the bottom of the high-frequency high-power density module power supply, wherein the power semiconductor assembly is arranged above the carrier element, and the carrier element is electrically connected with the power semiconductor assembly;
a bottom pin, the bottom pin being arranged at the bottom of a high-frequency high-power density module power supply;
An electrical connection assembly, the electrical connection assembly being used for electrically connecting the power semiconductor assembly to a bottom pin;
The top of the power semiconductor assembly is provided with a top heat dissipation structure;
The top heat dissipation structure comprises a top heat dissipation coating and a thermal connector, and the top heat dissipation coating is arranged on the upper surface of the first plastic packaging body through electroplating;
The thermal connector is disposed inside the first plastic package body, and the thermal connector thermally connects the at least one power semiconductor element with the top heat dissipation plating layer.

Preferably, wherein the electrical connection assembly is a flexible component, the flexible component is disposed on at least one side surface of the carrier element, the flexible component comprises at least one insulating layer and at least two conductive layers separated by the insulating layer, the flexible component at least comprises an overlapping region, and both sides of the insulating layer in the overlapping region have conductive layers and the electrodes of the conductive layer are opposite.

Preferably, a side rigid part is arranged on the flexible component, and the side surface of the rigid part comprises at least one of a rigid capacitor assembly and a rigid control assembly;
The rigid capacitor assembly comprises a third plastic package body and at least one side capacitor, the two electrodes of the side capacitor are electrically connected with different conductive layers of the flexible component respectively, and the third plastic package body wraps the side capacitor and at least one part of the conductive layer on the outer side of the flexible component;
The rigid control assembly comprises a control chip and a fourth plastic package, the fourth plastic package covers the control chip and at least a part of the conductive layer outside the flexible component, and the control chip is used for providing a control signal to the power semiconductor component.

Preferably, the outer side of at least one side rigid part is provided with a side metal plating layer by means of electroplating.

A parallel high-frequency high-power density module power supply combination comprises:
at least two high-power density module power supplies, a bottom pin is arranged on the bottom surface of the high-frequency high-power density module power supply, the bottom pin comprises a signal pin, an input power pin, an output power pin and a power grounding pin, the bottom surface is provided with a first edge, a second edge, a third edge and a fourth edge, the second edge is opposite to the fourth edge; the input power pin and the power grounding pin are alternately arranged on the second edge or the fourth edge of the bottom surface in an array;
The high-frequency high-power density module power supply is arranged in parallel, so that the second edge of one high-frequency high-power density module power supply is close to the fourth edge of the other high-frequency high-power density module power supply.

Preferably, a common radiator is arranged at the top of the parallel high-frequency high-power density module power supply combination.

The parallel high-frequency high-power density module power supply combination comprises:
a flexible and rigid combination assembly, comprising at least one rigid part and at least one flexible part; the at least one rigid part comprises a power semiconductor assembly; the rigid part and the flexible part are connected through a same flexible component, the rigid part is electrical connected with the bottom pin through the flexible component;
a carrier element, the rigid part is disposed on a surface of the carrier element; the flexible component wraps the top surface, at least a side surface of the carrier element and extends to the bottom of the carrier element, the bending position of the flexible component is the flexible part, the carrier element is electrical connected with the power semiconductor assembly;
the flexible component comprises at least one insulating layer and at least two conductive layers separated by the insulating layer, the flexible component comprises at least one overlapping region, and in the overlapping region, both sides of the insulating layer are provided with conductive layers, and the polarities of the electrodes of the conductive layer are opposite.

Preferably, the bottom pin comprises an output pin,
the first edge and the third edge are parallel, the output pin is arranged at the first edge or is not arranged on the bottom surface, and the signal pin array is arranged at the third edge;
The outer side of the second edge and the outer side of the fourth edge of the high-frequency high-power density module power supply are each provided with a client mainboard input capacitor, and the two electrodes of the client mainboard input capacitor are electrically connected with the input power pin and the power grounding pin respectively; and the common customer mainboard input capacitor is shared between every two adjacent high-frequency high-power density module power supplies. One electrode of the shared client mainboard input capacitor is electrically connected with the input power pins at the corresponding positions of the two adjacent high-frequency high-power density module power supplies, and the other electrode is electrically connected with the power grounding pins at the corresponding positions of the two adjacent high-frequency high-power density module power supplies.

A method for manufacturing a high-frequency high-power density module power supply, comprising:
Providing a carrier element;
a pre-formed flexible and rigid combination assembly;
Glue and solder are arranged on the surface of the carrier element, the glue is used for fixedly connecting the carrier element with the flexible and rigid combination assembly, and the solder is used for electrically connecting the carrier element with the flexible and rigid combination assembly;
The power semiconductor component is arranged on the upper surface of the carrier element, the flexible component is bent and extends to the bottom along the upper surface of the carrier element, and at least one side surface of the flexible component extends to the bottom, and the bending position of the flexible component is a flexible part;
Performing high-temperature treatment, melting and welding the solder, and curing and bonding the glue;
The pre-formed flexible and rigid combination assembly is specifically:
Providing a flexible component;
An electronic component required for the rigid part is provided on the flexible component or on the flexible component and inside the flexible component.

Preferably, after the electronic elements required by the rigid part are arranged on the flexible component or on the flexible component and in the flexible component, partially plastic packaging is carried out, and a rigid part is formed on the flexible component.

A manufacturing method of the high-frequency high-power-density module power supply comprises the following steps:
Providing a carrier element;
a pre-formed flexible and rigid combination assembly, wherein the step S2 is specifically as follows:
Providing a multi-layer PCB, at least one layer of the multi-layer PCB being a flexible PCB, and at least one layer being a rigid PCB;
Removing part of the rigid PCB, and exposing the flexible PCB as a flexible part;
Providing an electronic component on the multi-layer PCB or on the multi-layer PCB and in the multi-layer PCB board;
Performing plastic packaging to obtain a pre-plastic package body;
Removing part of the pre-plastic package to form a rigid part;
Glue and solder are arranged on the surface of the carrier element, the glue is used for fixedly connecting the carrier element with the flexibly and rigid combination assembly, and the solder is used for electrically connecting the carrier element with the flexible and rigid combination assembly;
The power semiconductor component is arranged on the upper surface of the carrier element, the flexible component is bent and extends to the bottom along the upper surface and at least one side surface of the flexible component, and the bending position of the flexible component is a flexible part;
Performing high-temperature treatment, melting and welding the solder, and curing and bonding the glue.

Preferably, the flexible and rigid combination assembly comprises a plurality of sets of flexible and rigid combination sub-assemblies which are connected in parallel and achieve the same function, and each set of flexible and rigid combination sub-assemblies comprises a rigid part, a flexible part, a flexible component and an end pin; testing each group of flexible and rigid combination sub-assemblies after high-temperature treatment, and cutting the flexible components corresponding to the flexible and rigid combination sub-assemblies to disconnect the flexible components corresponding to the flexible and rigid combination sub-assemblies.

A method for manufacturing a high-frequency high-power density module power supply, characterized in that the method comprises:
Providing a carrier element;
a pre-formed flexible and rigid combination assembly;
Glue and solder are arranged on the surface of the carrier element, the glue is used for fixedly connecting the carrier element with the flexible and rigid combination assembly, and the solder is used for electrically connecting the carrier element with the flexible and rigid combination assembly;
The power semiconductor component is arranged on the upper surface of the carrier element, the flexible component is bent and extends to the bottom along the upper surface and at least one side surface of the flexible component, and the bending position of the flexible component is a flexible part;
Performing high-temperature treatment, melting and welding the solder, and curing and bonding the glue;
The pre-formed flexible and rigid combination assembly is specifically:
Providing a multi-layer PCB, at least one layer of the multi-layer PCB being a flexible PCB, and at least one layer being a rigid PCB;
Removing part of the rigid PCB, and exposing the flexible PCB as a flexible part;
Providing an electronical component on the multi-layer PCB or on the multi-layer PCB and in the multi-layer PCB;
Performing plastic packaging to obtain a pre-plastic package body;
Punching holes in the upper portion of the pre-plastic package body, and electroplating the upper surface of the pre-plastic package body;
A portion of the pre-plastic package body is removed to form a rigid part.

A high-frequency high-power density module power supply is characterized by comprising:
a bottom pin, the bottom pin being arranged at the bottom of a high-frequency high-power density module power supply;
a carrier element, wherein at least one surface of the carrier element is provided with a surface power pin; the carrier element is arranged above the bottom pin;
At least one rigid part, wherein the rigid part comprises at least one power semiconductor assembly, the rigid part is provided with at least one power pin, the rigid part is electrically connected with the surface power pin, and the rigid part is arranged on the side surface of the carrier element.

Preferably, at least one side surface of the carrier element is provided with the surface power pin and is provided with the rigid part, and the power pin and the surface power pin of the rigid part are electrically connected nearby.

Preferably, the carrier element comprises an electrical conductor, and at least a part of the electrical conductor is parallel to the bottom of the high-frequency high-power density module power supply.

Preferably, wherein the carrier element comprises an integrated inductor, the integrated inductor comprises at least two windings, and the electrical conductor is a part of the winding.

Preferably, one end of the winding is located on the side surface of the carrier element, and the other end of the winding is located on the bottom face of the carrier element.

Preferably, the carrier element comprises at least one of a transformer, a capacitor combination or a sub-power supply module.

Preferably, at least two rigid parts are arranged; the rigid parts are arranged on different side surfaces of the carrier element respectively; and each rigid part comprises at least one power semiconductor assembly.

Preferably, at least two rigid parts are electrically connected through a flexible part; and at least one part of the flexible part is arranged on the upper surface of the carrier element.

Preferably, the flexible part is provided with an electronic element.

Compared with the prior art, the application has the following beneficial effects:
(1) the whole module system has only two main elements: a flexible and rigid combination assembly and a carrier element, the respective areas are large, control is easy during assembly, the interconnection is small, the space utilization rate is high, and the reliability and the assembly space can be relatively beneficial. The loop inductance is greatly reduced, the opportunity is less than 1 nH, the condition that the electrical performance is not sacrificed can be small, heat source placement is achieved, and heat dissipation treatment of the system is facilitated;
(2) the loop inductance is extremely small; the opportunity is as small as 0. 5 nH or below, and even an opportunity does not need to set Cin 1 in the module;
(3) on the premise that the electrical influence can be accepted, copper removal treatment is carried out in a stamp hole mode, the thickness of the metal layer at the bending position is reduced as much as possible, the force required by forming and the size loss caused by the forming angle are reduced, the reduction of the equivalent thickness is achieved, the uniformity of the equivalent thickness is kept, and the space utilization rate is greatly improved;
(4) the module pins are bent through the bottom of the flexible PCB, so that the area of the module pins is large, and welding is convenient. The deficiency is that the bending results in space occupation and process challenges. The size of the upper module electrode can be as small as 0.2 mm or even lower with the precision of the customer's ability to use. Then, even if the terminal side of the flexible PCB board is directly used for electroplating, the electrode can be led out. At least one bending is reduced, and the process challenge is greatly reduced;
(5) the top heat dissipation structure directly interconnects the wafer of the power semiconductor with the upper surface of the module, so that the thermal resistance between the semiconductor and the upper surface of the module is greatly reduced. Moreover, the upper surface after electroplating is flat and attractive, can effectively prevent moisture, and improves the reliability, quality and image of the product. The surface electroplated layer can be set to GND, and can effectively inhibit external radiation interference of the module.

### BRIEF DESCRIPTION OF THE DRAWINGS

In order to more clearly illustrate the embodiments of the present invention or the technical solutions in the prior art, the drawings required in the description of the embodiments or the prior art are briefly described below. It is obvious that the drawings in the following description are merely some embodiments of the present invention, and for a person of ordinary skill in the art, other drawings may be obtained according to these drawings without creative efforts.

FIG. 1A to FIG. 1C are schematic diagrams of a high-frequency high-power-density module power supply in the prior art.

FIG. 2 is a schematic diagram of a high-frequency high-power-density module power supply according to an embodiment of the present invention.

FIG. 3A to FIG. 3D are schematic diagrams of different arrangement positions between a rigid part and a carrier element of a high-frequency high-power-density module power supply according to an embodiment of the present invention.

FIG. 4A and FIG. 4B are schematic diagrams of a flexible part of a high-frequency high-power-density module power supply according to an embodiment of the present invention.

FIG. 5A to FIG. 5D are schematic diagrams of different viewing angles of a high-frequency high-power-density module power supply according to an embodiment of the present invention.

FIG. 6A to FIG. 6C are schematic diagrams of a flexible part of a high-frequency high-power-density module power supply according to an embodiment of the present invention.

FIG. 7A to FIG. 7D are various forming modes of a flexible and rigid combination assembly of a high-frequency high-power-density module power supply according to an embodiment of the present invention.

FIG. 8A to FIG. 8F are side capacitor structures of a high-frequency high-power-density module power supply according to an embodiment of the present invention.

FIG. 9A and FIG. 9B are pin structures of a high-frequency high-power-density module power supply according to an embodiment of the present invention.

FIG. 10A and FIG. 10B are pin electroplating structures of a high-frequency high-power-density module power supply according to an embodiment of the present invention.

FIG. 11A and FIG. 11B are top heat dissipation structures of a high-frequency high-power-density module power supply according to an embodiment of the present invention.

FIG. 12A and FIG. 12B are a controller structure of a high-frequency high-power-density module power supply according to an embodiment of the present invention.

FIG. 13 is a manufacturing method of a high-frequency high-power-density module power supply according to an embodiment of the present invention.

FIG. 14A and FIG. 14B are specific manufacturing methods of a high-frequency high-power-density module power supply according to an embodiment of the present invention.

FIG. 15 is a typical application of a high-frequency high-power-density module power supply according to an embodiment of the invention.

FIG. 16A to FIG. 16D are other typical applications of a high-frequency high-power-density module power supply according to an embodiment of the present invention.

FIG. 17 shows a multi-path control structure of a high-frequency high-power-density module power supply according to the embodiment.

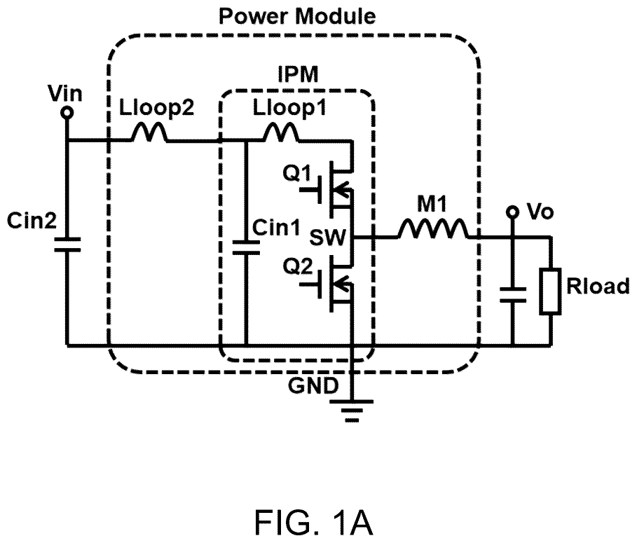

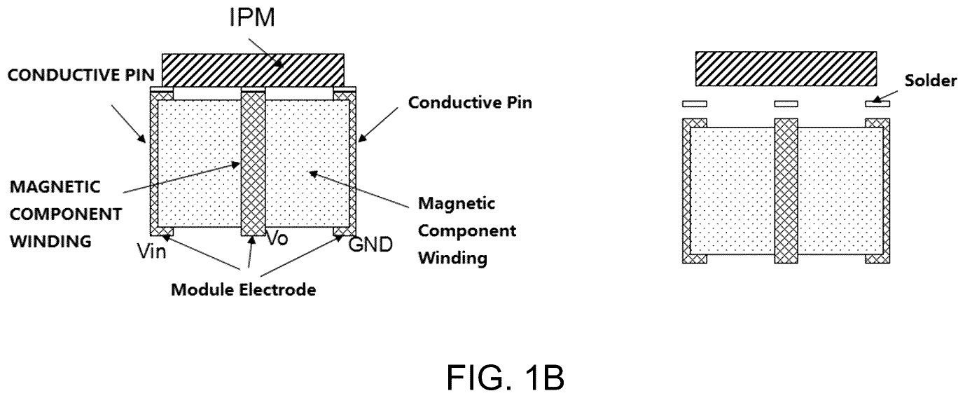

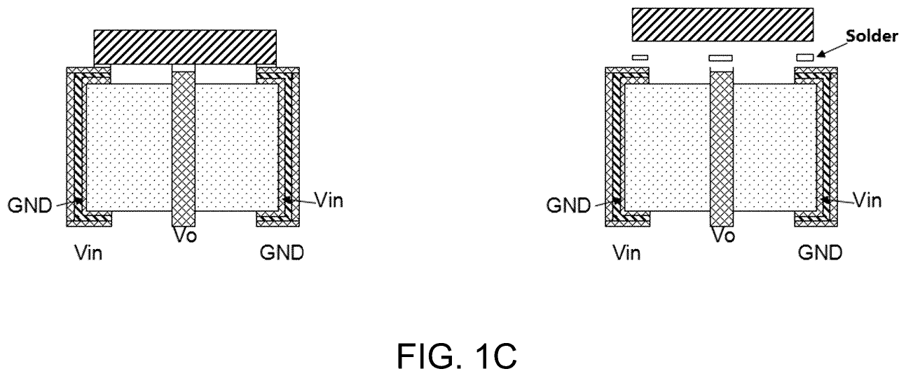

### DESCRIPTION OF THE EMBODIMENTS

Disclosed in the present invention are a high-frequency high-power density module power supply and a manufacturing method therefor. The high-frequency high-power density module power supply comprises: a carrier element, wherein at least one surface of the carrier element is provided with a surface power pin; and a flexible and rigid combination assembly, wherein the flexible and rigid combination assembly comprises at least one rigid part and at least one flexible part, the at least one rigid part comprises a power semiconductor assembly, and the rigid part is electrically connected to the flexible part. At least one part of the flexible and rigid combination assembly is electrically connected to the surface power pin of the carrier element; the flexible and rigid combination assembly is bent by using the surface of the carrier element as a carrier, and a bent part is the flexible part; the rigid part and the flexible part are connected by means of the same flexible component, and the at least one rigid part and/or the flexible component are/is provided with at least one power pin. According to the present invention, a heat dissipation capability is ensured, and the loop inductance is greatly reduced, so that high-power high frequency is realized, and an application basis is provided for updating the performance of the high-power high frequency.

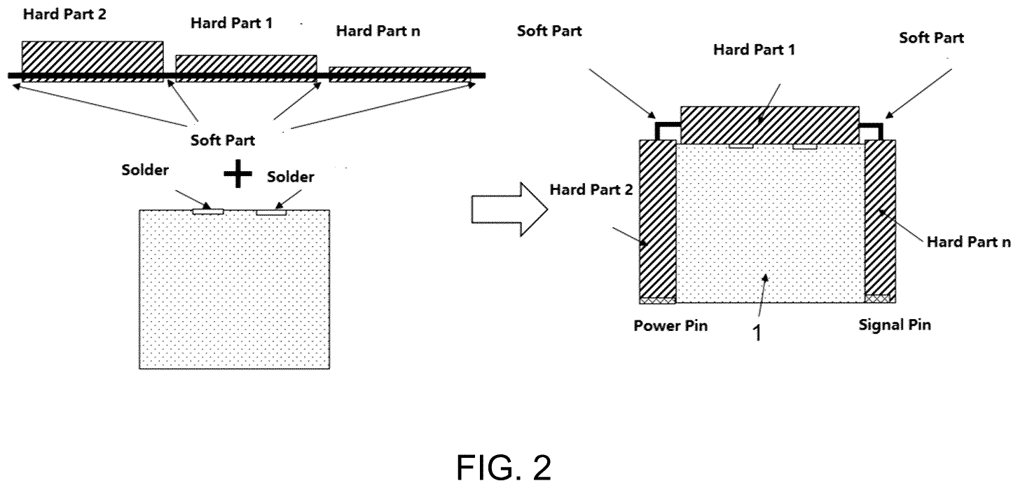

FIG. 2 shows a high-frequency high-power-density module power supply module according to the embodiment. The high-frequency high-power-density module power supply module comprises:
a carrier element 1, wherein at least one surface of the carrier element 1 is provided with a surface power pin; the carrier element 1 in the embodiment is not necessarily an inductor, and can be a transformer or a capacitor combination or even a sub-power supply module;
A flexible and rigid combination comprises at least one rigid part 2 and at least one flexible part 3, the at least one rigid part 2 comprises a power semiconductor assembly, and the power semiconductor assembly can be used for a power conversion circuit, such as a boost circuit or a step-down circuit; the rigid part 2 is electrically connected with the flexible part 3;
At least one of the flexible and rigid combination assemblies is electrically connected to a surface power pin of the carrier element 1;
The flexible and rigid combination assembly is bent by taking the surface of the carrier element 1 as a carrier, and the bending position is a flexible part 3;
The rigid part 2 and the flexible part 3 are interconnected by the same flexible component 4, and the at least one rigid part 2 and/or the flexible component 4 have at least one power pin.

Preferably, the flexible part 4 is a flexible board, and each rigid part 1 is respectively arranged at different positions of the flexible board 4. A person skilled in the art can understand that the arrangement position of each rigid part 2 on the flexible board 4 can be set according to needs, the center line of each rigid part 2 can be respectively located above, in the middle or below the flexible board 4, and the thickness of each rigid part 2 can also be set according to needs; the length and the width of each flexible part 3 can also be set according to requirements, the number of the rigid parts 2 and the number of the flexible parts 3 can also be freely adjusted, and the built-in elements of the rigid parts 2 can also be freely adjusted according to the requirements of the circuit.

The high-frequency high-power density module power supply module of the embodiment has only two main elements: a carrier element 1 and a flexible and rigid combination assembly, the respective areas of the two main elements are large, it's easy to control during assembly, the interconnection between the two main elements is less, the space utilization rate is high, and the reliability and the assembly space can be relatively beneficial. The loop inductance is greatly reduced, which can be smaller than 1 nH. In the situation that the electrical performance is not sacrificed, heat source is placed above, and heat dissipation treatment of the system is facilitated.

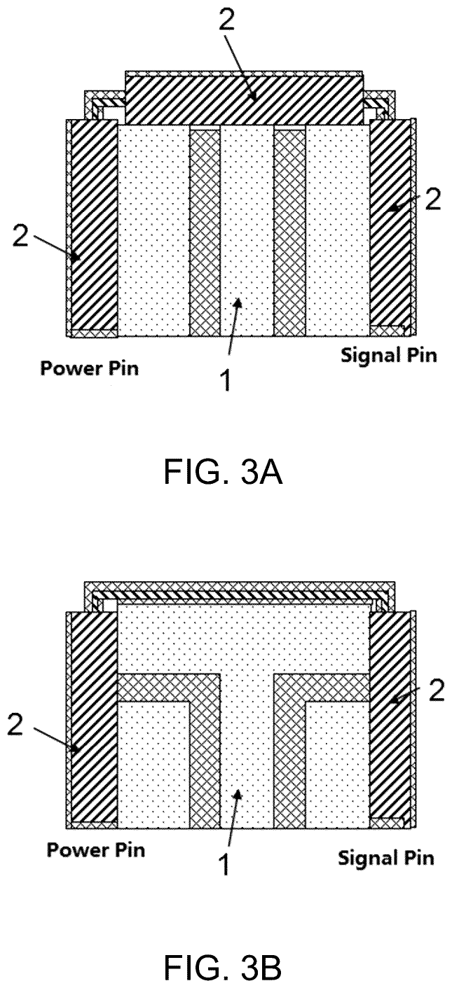

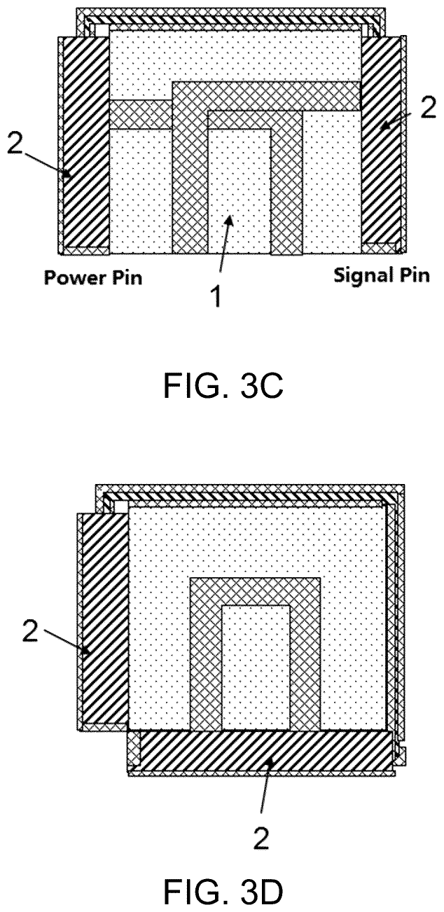

FIG. 3A to FIG. 3D show schematic diagrams of different arrangement positions between a rigid part 2 and a carrier element 1 of a high-frequency high-power density module power module according to the embodiment; as shown in FIG. 3A. A rigid part 2 containing a power semiconductor assembly is arranged on the upper surface of the carrier element 1, and the rigid part 2 is connected with the carrier element 1 on the upper surface of the carrier element 1. It is suitable for an application scene with a small occupied area; the rigid part 2 arranged on the side surface of the carrier element 1 is a rigid part 2 without a power semiconductor assembly as shown in FIG. 3A, a person skilled in the art can arrange a built-in element according to needs.

As shown in FIG. 3B, the rigid part 2 containing the power semiconductor assembly is arranged on the side surface of the carrier element 1, power interconnection with the carrier element 1 is carried out on the side surface of the carrier element 1, and the method is suitable for an application scene with a short module height, that is, the upper surface of the carrier element 1 is not provided with the rigid part 2 containing the power semiconductor assembly. As shown in FIG. 3C, the at least two rigid parts 2 comprise power semiconductor components which are respectively arranged on two different side surfaces of the carrier element 1 and are suitable for application scenes with short module heights and high power In a preferred embodiment, when the two step-down circuits are used in parallel, the carrier element 1 is an integrated inductor, and in order to obtain excellent dynamic response, the integrated inductor is an inductor containing two anti-coupling windings. As shown in FIG. 3D, the rigid part 2 containing the power semiconductor assembly is arranged on the lower surface of the carrier element 1, and is in power interconnection with the carrier element 1 on the lower surface of the carrier element 1; It is suitable for an application scene below the carrier element 1 in the heat dissipation channel.

A person skilled in the art can understand that FIG. 3A to FIG. 3D are merely schematic diagrams illustrating different arrangement positions between several rigid parts 2 and a carrier element 1 as preferred embodiments, and other technical solutions not shown in different arrangement positions between the rigid part 2 and the carrier element 1 are also within the protection scope of the present invention.

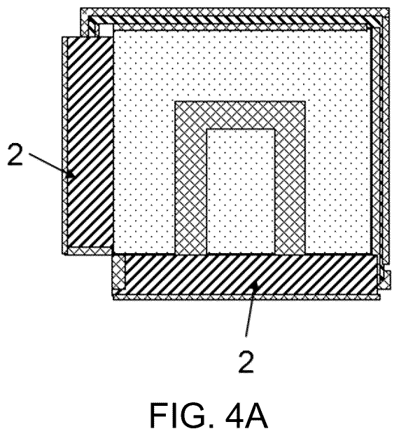

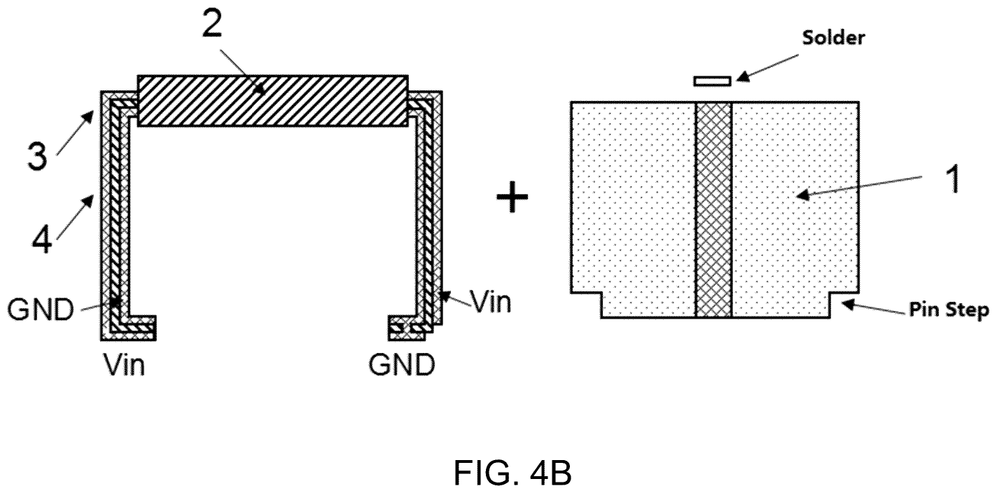

FIG. 4A and FIG. 4B show schematic diagrams of a flexible component 4 of a high-frequency high-power-density module power supply module according to the embodiment. The flexible component 4 comprises at least one insulating layer and at least two conductive layers separated by the insulating layer. The flexible component 4 comprises at least one overlapping region. In the overlapping region, both sides of the insulating layer are provided with conductive layers, and the electrodes of the conductive layer are opposite to each other. One end of the electrode is grounded, and the other end of the electrode is connected with the input power or the output power end so as to reduce the loop inductance. The end of the flexible component 4 is provided with an end pin, and the end pin comprises at least one power pin.

In a preferred embodiment, the flexible component 4 is a flexible PCB board, and the flexible PCB board at least comprises a double-layer metal layer, and the electrical low-parasitic inductance of the rigid part 2 is led out to the end pin. Taking the 2 oz copper thick flexible PCB as an example, the total thickness of the flexible PCB can be smaller than 0.2 mm, and the overall volume influence on the module can be almost ignored. The thickness of the insulating layer is less than 50 um, so that extremely ideal low-loop inductive power or signal transmission is realized. The loop inductance can be small or less than 0. 5 nH, and even Cin1 isn't needed in the module.

In some other embodiments, as shown in FIG. 4A and FIG. 4B, the pin is formed on one surface of the carrier element 1 after being bent by the flexible component 4. Preferably, one surface of the carrier element 1 is provided with a space for accommodating the end pin as a bending space of the module pin, and the thickness of the module caused by the thickness of the pin is reduced. A person skilled in the art can understand that the bending position of the end pin is a flexible part 3.

In a preferred embodiment, the conductive layer disposed between the flexible component 4 and the carrier element 1 is an inner conductive layer 5, the outer conductive layer 6 is disposed outside the flexible component 4, and the inner conductive layer 5 is electrically connected to the at least one end pin by penetrating the flexible component 4, as shown in the GND portion at the lower right corner of FIG. 4A.

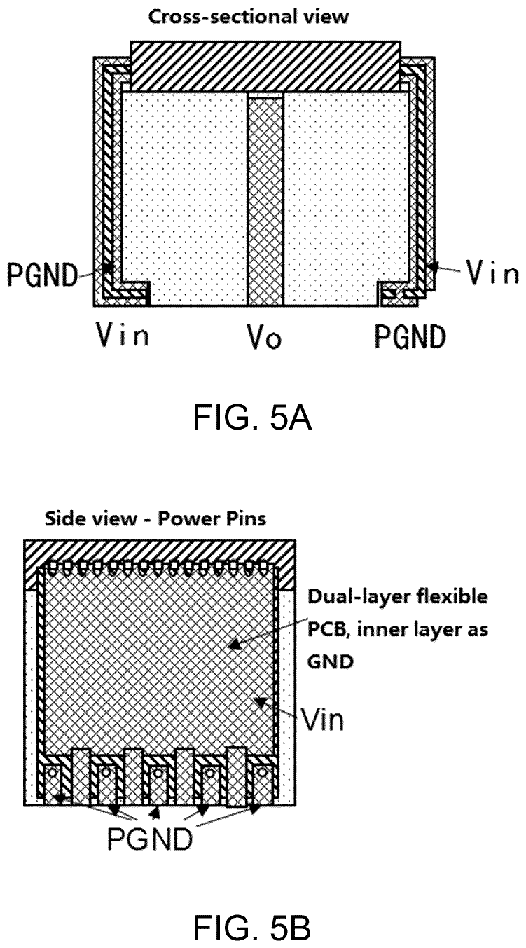

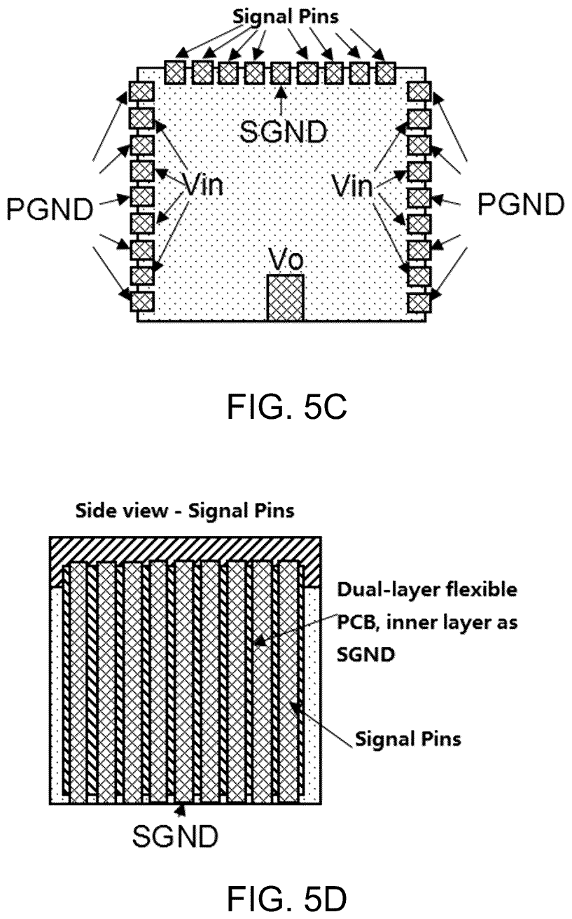

FIG. 5A to FIG. 5D show schematic diagrams of different viewing angles of a high-frequency high-power-density module power supply module according to the embodiment, not only a power pins can be reduced the loop path through the overlapped and coupled by a double-layer metal layer of the flexible component 4, and signal pins of the module can also be realized through the coupled double layers. The inner metal layer of the double-layer metal layer close to the inductor is GND, the inductance of the signal loop is reduced, and meanwhile interference of magnetic element leakage flux on signal transmission is shielded.

As shown in FIG. 5A, the plurality of side surfaces of the carrier element 1 can be used for arranging the flexible component 4, can have a larger area of power pin transmission, reduce transmission loss, and further reduce a loop; and the power pin and the signal pin can also be arranged in different surface, mutual interference is reduced, and convenience is provided for customer use, as shown in FIGS. 5B and 5D.

In a preferred embodiment, the end pin further comprises a power ground pin PGND, and the power pin and the PGND are arranged in a staggered manner, as shown in FIG. 5B and FIG. 5C, so as to reduce the increasing loop inductance caused by large but less power pins when the client application is reduced. The inner-layer metal electrode is close to the pin, and the inner-layer metal electrode can become an effective module pin only through the flexible component 4 shown in FIG. 4A.

As shown in FIG. 5B, most of the metal layer on one side, close to the carrier element 1, of the flexible component 4 is a GND layer, so that the voltage difference formed by the electrodes on the carrier element 1 is reduced, and electric leakage is possibly caused.

In a preferred embodiment, three side surfaces of the carrier element 1 are provided with flexible components 4, and the left and right sides are both a power pin combination (such as input), a signal pin combination and another power pin combination (such as output).

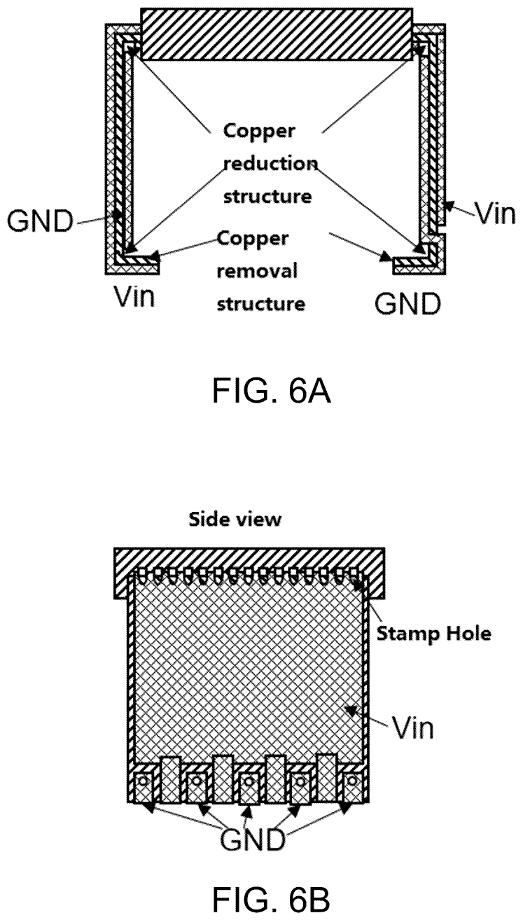

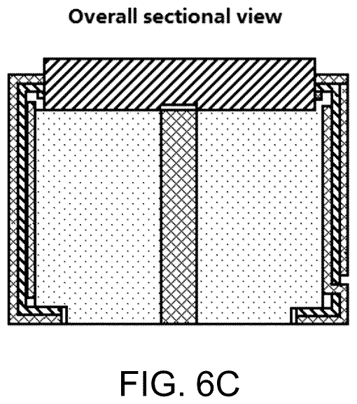

FIG. 6A to FIG. 6C show a schematic diagram of a flexible part 3 of a high-frequency high-power-density module power supply module according to the embodiment. The flexible and rigid combination assembly needs to be bent, the bent part of the flexible and rigid combination assembly is treated, the process difficulty is not involved, and the space utilization rate is also influenced. Therefore, on the premise that the electrical influence can be accepted, the thickness of the metal layer at the bending position should be reduced as much as possible to reduce the force required for forming and the size loss caused by the forming angle.

In the embodiment, the flexible component 4 has a copper reduction structure to form a flexible part, and the copper reduction structure is of a thinned structure or a stamp hole structure. The metal layer copper of the flexible component 4 is partially etched and removed, and the stamp holes of the inner and outer metal layers of the flexible component 4 at the bending position can be arranged in a crossed mode, so that the equivalent thickness is reduced, and the uniformity of the equivalent thickness is kept. The traditional bending angle cannot be larger than 45 degrees, and the bending angle can be larger than 60 degrees and is greatly improved.

In other embodiments, the flexible component 4 has a copper removal structure to form a flexible part, and when the flexible part is bent to a pin at the lower surface of the carrier element 1, the metal layer of the bent part of the flexible part 3 and the metal layer close to one surface of the carrier element 1 is removed, so that the bending stress and the overall thickness of the module are reduced.

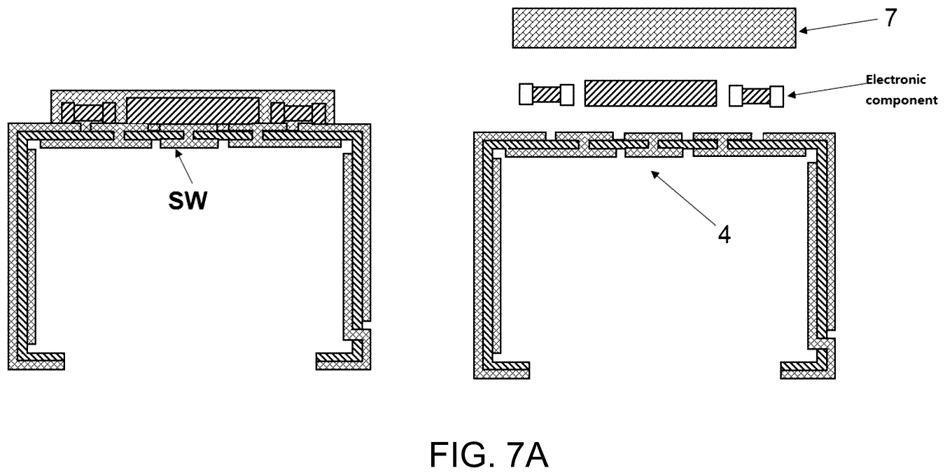

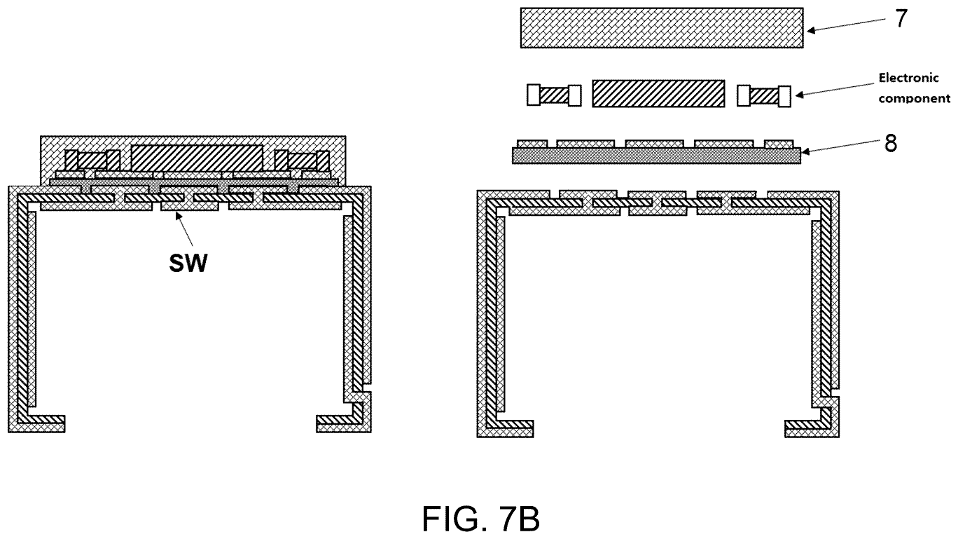

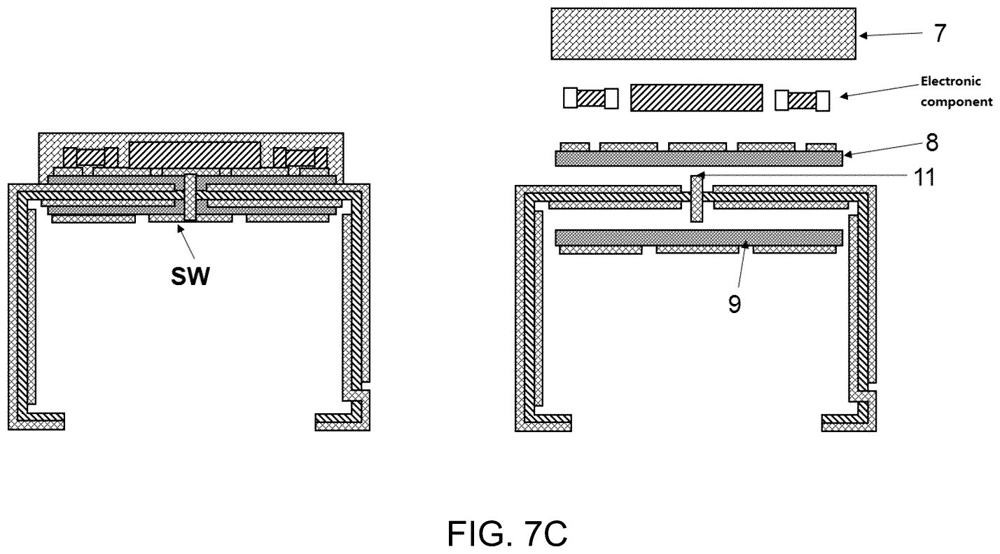

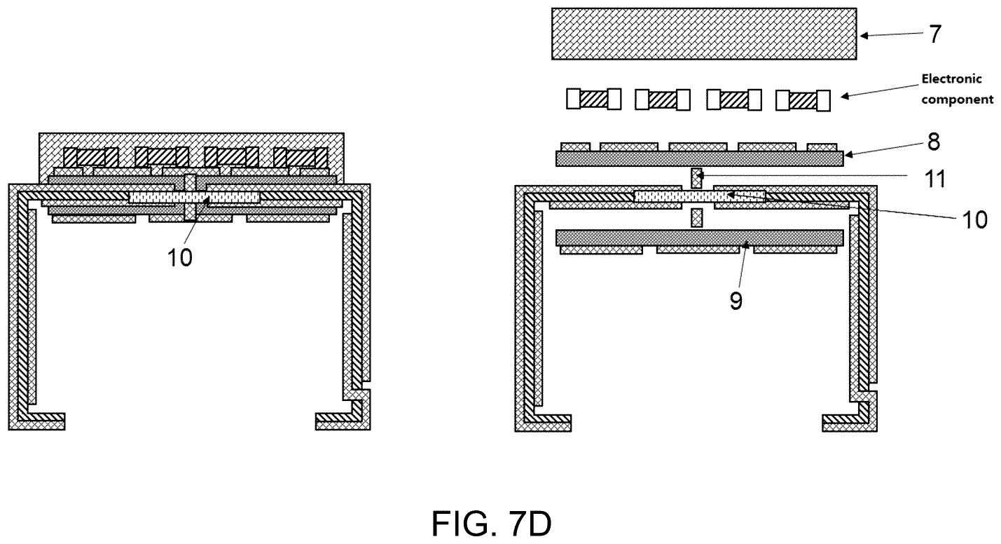

FIG. 7A to FIG. 7D show various forming modes of the flexible and rigid combination assembly of the high-frequency high-power-density module power module according to the embodiment, as shown in FIG. 7A, the power semiconductor assembly comprises a power semiconductor element and a first plastic package body 7 which are arranged on the upper surface of the flexible component 4, the power semiconductor element is electrically connected with the flexible component 4, and the first plastic package body 7 wraps the power semiconductor element and at least one part of the upper surface of the flexible component 4. Specifically, after a power semiconductor element and a necessary peripheral device are placed on a multilayer flexible board, partial plastic packaging is performed to form a rigid part 2.

As shown in FIG. 7B, in a preferred embodiment, since the flexible board needs to maintain bendability, the number of layers thereof is not more than two, and the internal electrical interconnection of the rigid part 2 often requires more layers. Therefore, the traditional idea is generally that the PCB can be additionally placed on the flexible board. For example, a multi-layer PCB board is welded on the flexible board, and power semiconductor elements and necessary peripheral devices are placed on the multi-layer PCB board. However, the scheme needs to be welded and formed, and the interconnection precision between the layers of PCBs is low. Therefore, the power semiconductor assembly of the embodiment comprises a first PCB 8 arranged on the upper surface of the flexible component 4, a power semiconductor element arranged on the first PCB 8 and a first plastic packaging body 7, the power semiconductor element is electrically connected with the flexible component 4 through the first PCB 8, the first plastic packaging body 7 wraps the first PCB 8 and the power semiconductor element, a PCB production process is selected, a double-layer flexible plate is used as a basis, a required PCB is pressed on the double-layer flexible plate, and high-strength and high-precision interconnection is carried out through punching and electroplating. The multi-layer PCB is laminated, namely the rigid part 2 of the embodiment.

As shown in FIG. 7C, in a preferred embodiment, the power semiconductor assembly further comprises a second PCB 9 arranged on the lower surface of the flexible component 4, and the first PCB 8 is electrically connected with the second PCB 9 through a via hole electric connector 11 arranged in the via hole. Multiple layers of PCBs are laminated on the upper surface and the lower surface of the flexible PCB, and high-strength and high-precision interconnection is carried out through punching and electroplating, so that the symmetry of the structure is realized, and warping is reduced.

As shown in FIG. 7D, in a preferred embodiment, the flexible component 4 is internally provided with an embedded wafer 10 in a region corresponding to the rigid part 2, and the embedded wafer 10 is respectively connected to the first PCB 8 and the second PCB board 9 by means of the via hole electrical connector 11. According to the embodiment, the embedded wafer 10 is embedded in the flexible component 4, the embedded wafer 10 can be the power semiconductor wafer to reduce the thickness of the rigid part 2, that is, the thickness of the module is reduced, and the embodiment is particularly suitable for a module with the total thickness below 5 mm. That is to say, the power semiconductor assembly further comprises at least one embedded wafer 10, the embedded wafer 10 is arranged in the first PCB 8 and/or between the first PCB 8 and the flexible component 4 and/or in the flexible PCB, and the embedded wafer 10 is electrically connected with the first PCB 8 and/or the flexible component 4.

As shown in FIG. 7B to FIG. 7D, in other embodiments, due to the increase of the number of layers of the PCB, the strength of the rigid part 2 meets the requirements, but partial plastic packaging can still be selected, so that the reliability and the strength are further improved, and a user can conveniently install the radiator on a heat dissipation interface.

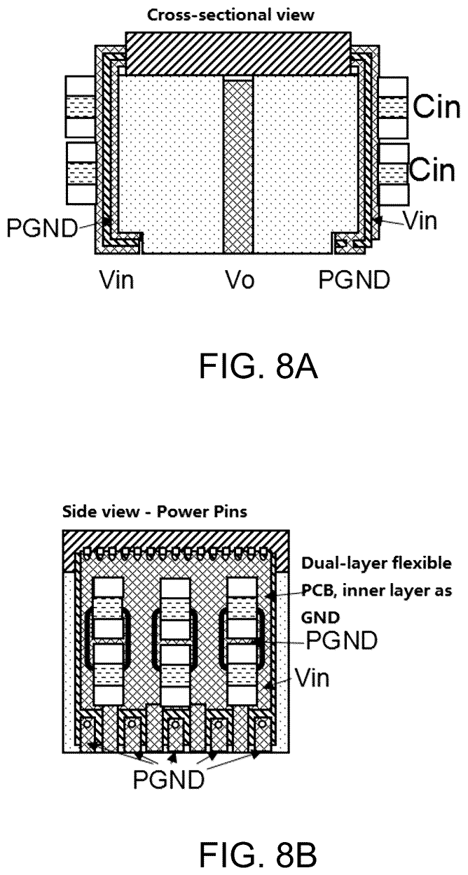

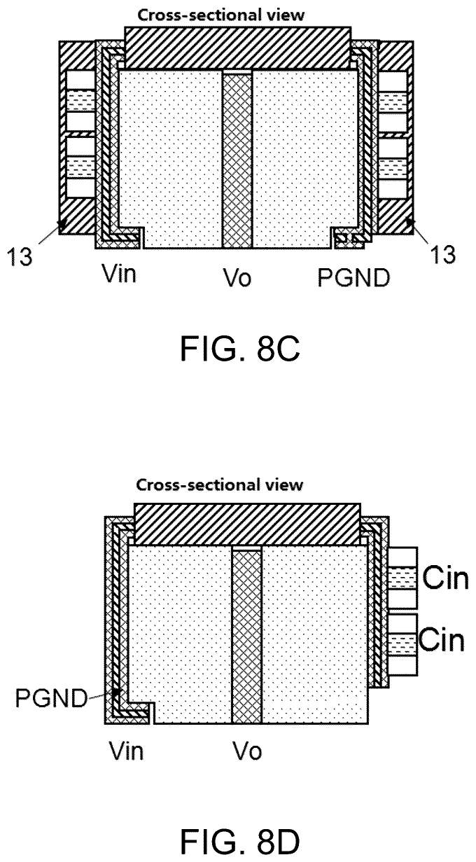

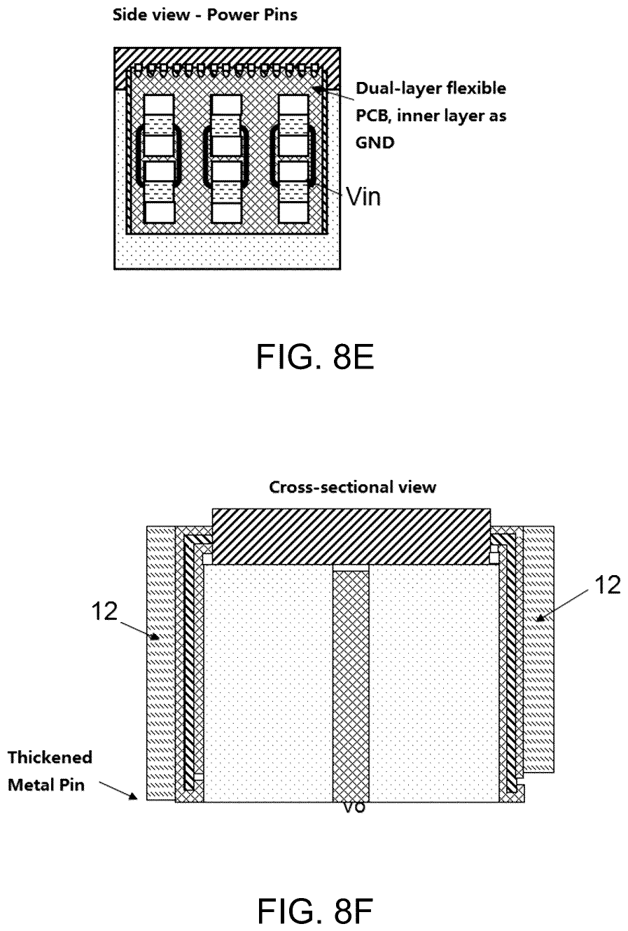

FIG. 8A to FIG. 8F show the side capacitor structure of the high-frequency high-power-density module power supply module according to the embodiment. In some application occasions, it is necessary to pursue the height of the module height, and it is desirable that the module integrates as many elements as possible. Therefore, in the embodiment, due to the introduction of the flexible multi-layer PCB, the electronic element can also be placed on the flexible component 4 to form a rigid part 2 on the flexible component 4, for example, the Cin1 is moved from the rigid part 2 at the top to the flexible component 4 on the side surface of the carrier element 1, so that the height of the module is reduced; for example, the Cin2 is moved from the client mainboard to the flexible component 4 on the side surface of the carrier element 1, so that the assembly required by the client is reduced, the height space of the client mainboard is fully utilized, and the Lloop2 is greatly reduced. That is to say, the rigid part 2 of the present embodiment may comprise a side capacitor provided on the flexible component 4.

In FIG. 8B and FIG. 8D, the inner layer PGND of the flexible PCB board is led out to the outer layer in a part of the side surface and is used for being electrically connected with the pin of the capacitor (the plurality of capacitors is horizontally placed on the client mainboard, and the upper part of the client mainboard is wasted. When the module part is equivalent to stacking, the height is fully utilized, the occupied area is smaller.) A traditional module, especially a high-frequency large-current module, due to the importance of Lloop2, results in different effects of different clients, and a large amount of customer service work is caused. The integration of Cin2 greatly reduces the difficulty of customer use.

As shown in FIG. 8C, in a preferred embodiment, the local position of the electronic element is placed on the flexible component 4, plastic packaging can also be achieved, the reliability is improved, the insulation capability of the customer during use is improved, and the utilization rate of the plastic packaging mold is greatly improved. That is to say, the rigid part 2 of the embodiment comprises a side capacitor and a second plastic package 13 which are arranged on the flexible component 4, and the second plastic package 13 wraps the side capacitor and at least one part of the flexible component 4.

As shown in FIG. 8F, in a preferred embodiment, due to the fact that the copper thickness of the flexible PCB is often within 0.1 mm, the current carrying capacity is limited, metal blocks such as thick copper can be added on the PCB, and the current carrying capacity is improved. The thickened metal block 12 can be only used as a current carrying and can also be used as a pin area for increasing use. That is to say, the rigid part 2 of the embodiment comprises a thickened metal block 12 arranged on the flexible component 4, and the thickened metal block 12 is electrically connected with the flexible component 4.

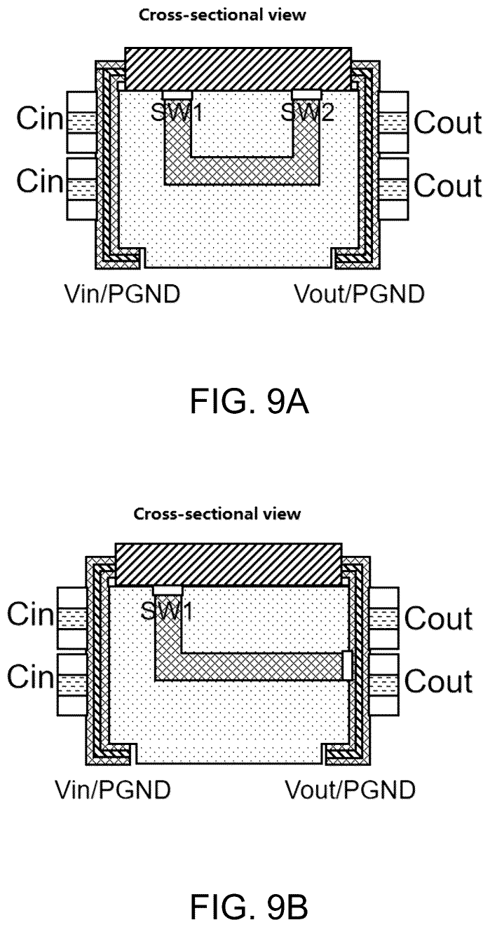

As shown in FIG. 9A and FIG. 9B, the PIN structure of the high-frequency high-power density module power supply module of the embodiment is shown, and all pins of the carrier element 1 are not arranged on the lower surface of the carrier element 1. That is, the lower surface of the module. Due to the fact that at least one power electrode input or output of the Buck circuit or the Boost circuit is the same electrode as one electrode of the magnetic element, in order to reduce interconnection loss caused by pins, the output electrode of the Buck circuit or the input electrode of the Boost circuit can be directly used as a module electrode by taking the carrier element 1, namely the corresponding electrode of the magnetic element. However, the electrode of the carrier element 1 of a plurality of circuits is an internal electrode of the module, or in order to reduce the difficulty of processing the flatness of the module pin, the electrode of the carrier element 1 is not directly used as the electrode of the module electrode. When the module is Buck-Boost, the carrier element 1 is an inductor, and the two electrodes are both arranged on the upper surface and are interconnected with two high-frequency points SW1 and SW2 at the bottom of the IPM. In order to solve the flatness problem, the electrode of the carrier element 1 and the electrode of the module with the same electrical property are electrically connected with the flexible component 4 through the side surface, and then are led out.

The module pins of the high-frequency high-power density module power supply module in the embodiment are obtained by bending the bottom of the flexible PCB. The advantage is that the area of the module pin is large, and welding is convenient. The defect is that the bending causes space occupation and process challenges.

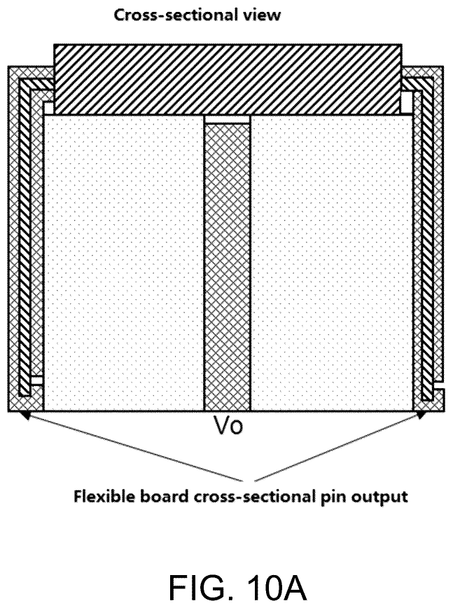

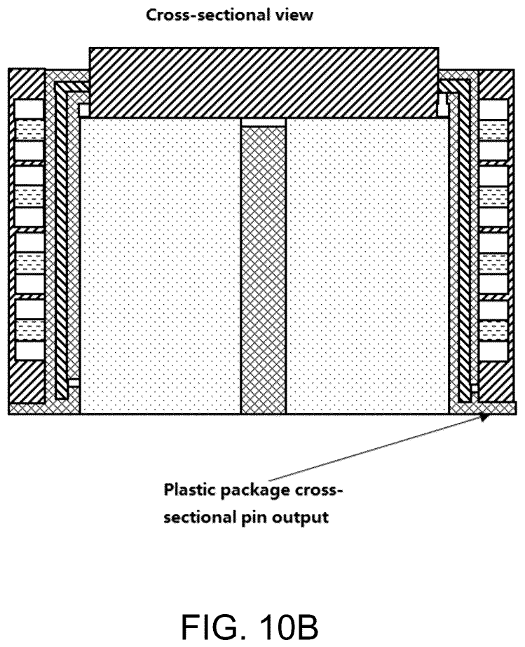

FIG. 10A and FIG. 10B show a pin electroplating structure of a high-frequency high-power-density module power supply module according to the embodiment. The size of the upper module electrode can be as small as 0.2 mm or even lower. According to the embodiment of the invention, the end section of the flexible component 4 is electroplated to realize electrode leading-out. At least one bending is reduced, and the process challenge is greatly reduced.

As shown in FIG. 10B, in a preferred embodiment, if the flexible component 4 has been provided with the second plastic package body 13 as shown in FIG. 8C, the end section of the second plastic package body 13 can be used for electroplating and leading out the module pin, so that the area and strength of the pin can be increased. That is to say, at least one rigid part 2 is a rigid capacitor assembly, the bottom of the rigid capacitor assembly is flush with the bottom of the carrier element 1, and at least one end pin is arranged at the bottom of the rigid capacitor assembly through electroplating.

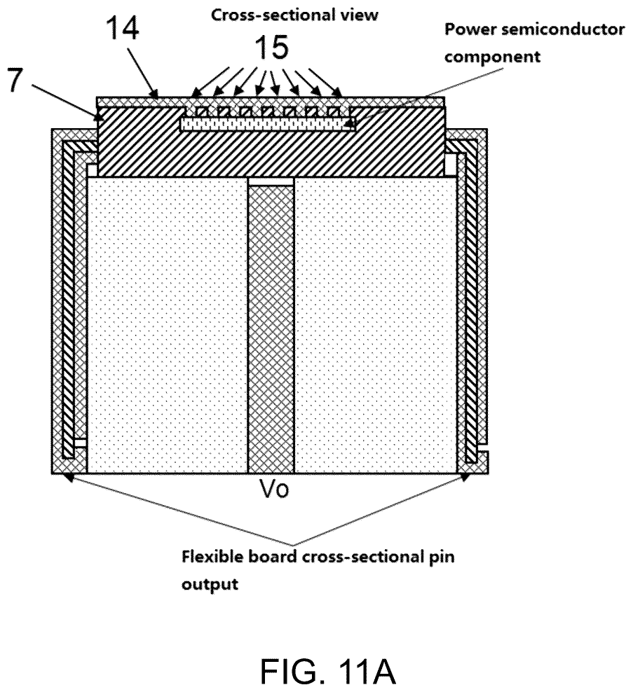

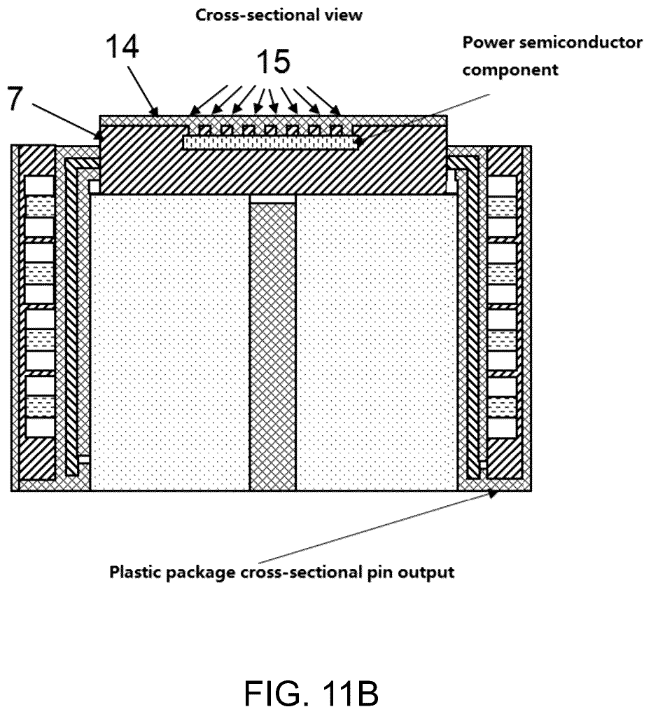

FIG. 11A and FIG. 11B show a top heat dissipation structure of a high-frequency high-power density module power supply module According to the embodiment of the invention, in the process of pre-forming the flexible and rigid combination assembly, a heat dissipation structure is formed on the surface of the plastic package through punching and electroplating, the wafer of the power semiconductor is directly thermally interconnected with the upper surface of the module, and the thermal resistance between the semiconductor and the upper surface of the module is greatly reduced. Moreover, the upper surface after electroplating is flat and attractive, can effectively prevent moisture, and improves the reliability, quality and image of the product. The surface electroplated layer can be set to GND and can effectively inhibit external radiation interference of the module. In the traditional scheme, due to the existence of the plastic packaging material, the thermal resistance from the power semiconductor to the top of the module is greater than 10K/W or even higher. According to the embodiment, the thermal resistance can be reduced to less than 5K/W or even lower, and the working power or the applicable environment temperature is greatly improved. That is to say, the power semiconductor assembly of the embodiment comprises a power semiconductor element and a first plastic packaging body 7, the first plastic packaging body 7 wraps the power semiconductor element, a top heat dissipation structure is arranged at the top of the power semiconductor assembly, the top heat dissipation structure comprises a top heat dissipation coating 14 and a thermal connector 15, the top heat dissipation coating 14 is arranged on the upper surface of the first plastic packaging body 7 through electroplating, the thermal connector 15 is arranged in the first plastic packaging body 7, and the thermal connector 15 is used for thermally connecting the at least one power semiconductor element with the top heat dissipation coating 14.

In the prior art, in a large-current occasion, a main power semiconductor and a controller are difficult to realize on one wafer. Due to the fact that the current is large, the requirement for the size of the wafer is large. Therefore, it is difficult to simultaneously set the controller and the main power semiconductor in the IPM area at the top of the module. Due to the structural problem in the prior art, the controller can only be solved by the client on the mainboard, and the use difficulty of the module is greatly improved.

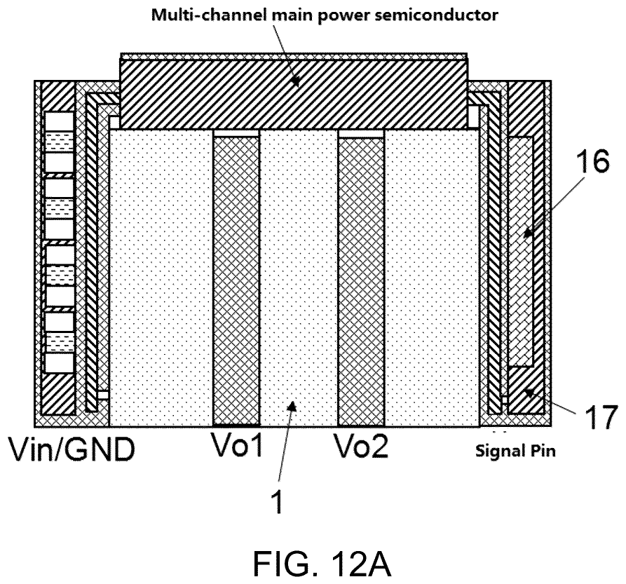

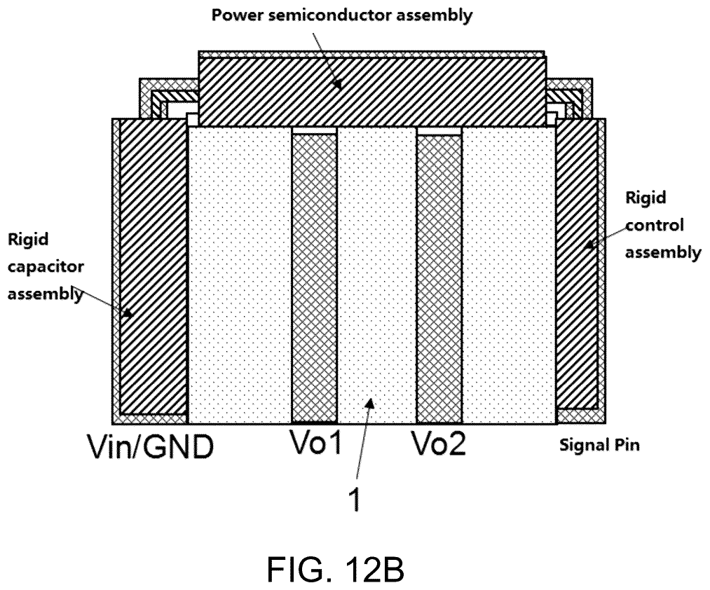

FIG. 12A and FIG. 12B show a controller structure of a high-frequency high-power-density module power supply module according to the embodiment. A controller is arranged on the flexible component 4, the signal pins are directly led out to the module, and the use convenience of the module is greatly improved under the condition that the limited thickness is increased.

In a preferred embodiment, the main power semiconductor also requires a plurality of wafers to be implemented together, typically a combination of two main power semiconductor accepting interleaved parallel control is used as a module. Then, the corresponding magnetic element is also a multi-path integrated element.

In a preferred embodiment, the positions of electronic components on the flexible and rigid combination are plastic packaged or even electroplated. However, due to the fact that the height of each part is different, the plastic package with the step thickness can be used, or the plastic package is locally thinned after plastic packaging.

That is to say, the at least one rigid part 2 is a rigid control assembly, the rigid control assembly is arranged on the outer conductive layer 6 of the flexible assembly 4 on at least one side, the rigid control assembly comprises a control chip 16 and a third plastic package 17, the third plastic package 17 wraps the control chip 16 and at least one part of the outer conductive layer 6 of the flexible assembly 4, and the control chip 16 is used for providing a control signal for the power semiconductor assembly.

In a preferred embodiment, the bottom of the rigid control assembly is flush with the bottom of the carrier element 1, and at least one end pin is disposed at the bottom of the rigid control assembly by electroplating.

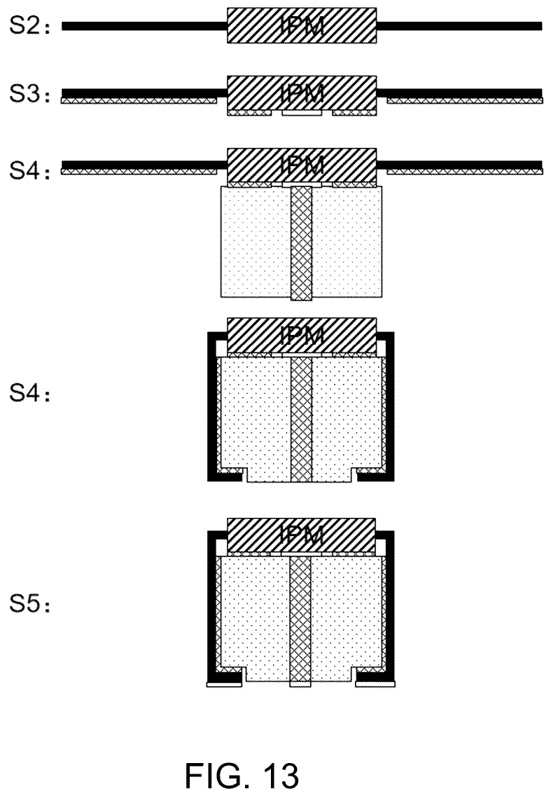

FIG. 13 shows a manufacturing method of a high-frequency high-power-density module power supply module according to the embodiment:

Step S1: providing a carrier element 1.

Step S2: pre-forming the flexible and rigid combination assembly.

And S3, arranging glue and solder on the surface between the flexible and rigid combination assembly and the carrier element 1.

S4, placing the carrier element 1 at the corresponding position of the flexible and rigid combination assembly, according to requirements, and carrying out bending by taking the surface of the carrier element 12 as a support; and then melting and welding the solder at a high temperature, and curing and bonding the glue.

And S5, optionally, if necessary, grinding the surface of the pin of the module, placing the solder and soldering flux treatment, or placing the thickening solder and then polishing, so as to ensure the pin flatness and weldability of the module.

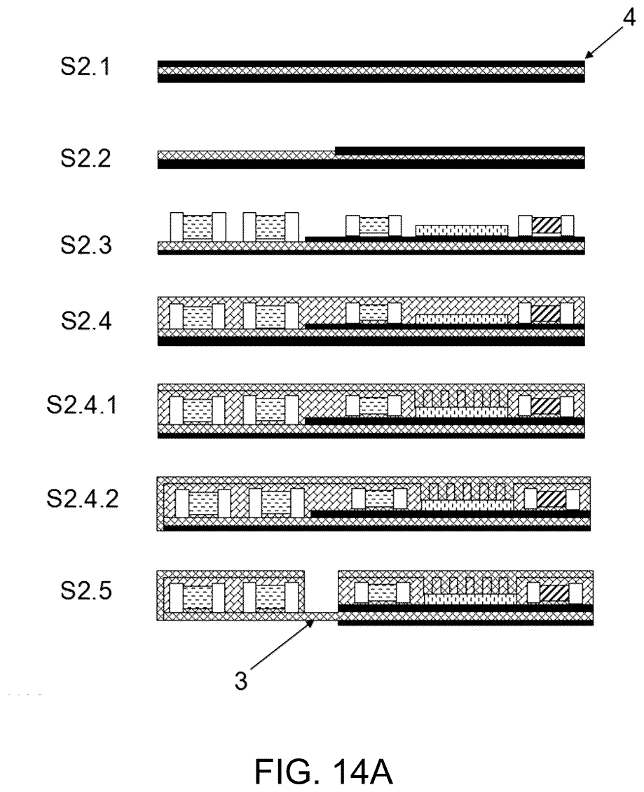

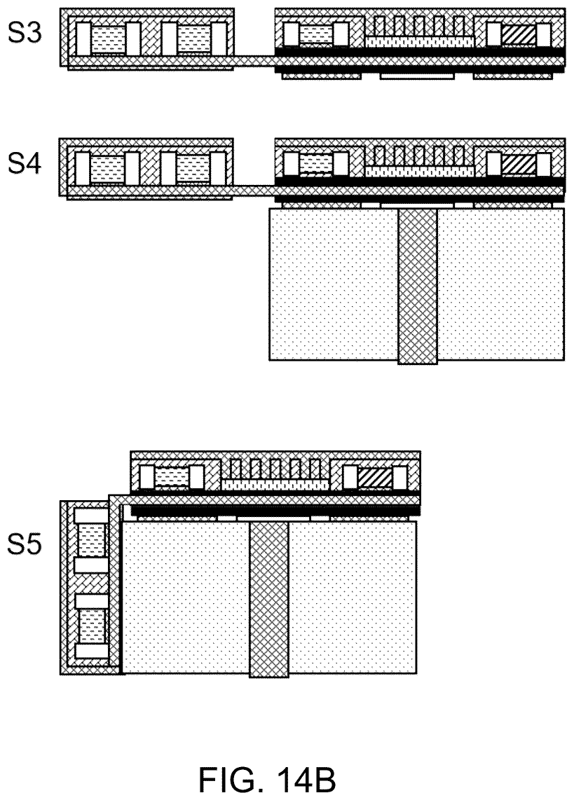

FIG. 14A shows the specific process of the step S2, and comprises the following steps:

S2.1, providing a flexible component 4, wherein the flexible component 4 is a multi-layer PCB embedded with a flexible PCB; prefabricating and forming the multi-layer PCB with the embedded flexible PCB; and if a PCB embedded element is arranged, completing the embedded step in this step.

Step S2.2, removing part of the rigid PCB on the upper surface of the flexible component 4 to expose the flexible PCB.

Step S2.3, placing and welding the electronic component on the flexible component 4.

Step S2.4: performing plastic packaging on the electronic component on the flexible component 4.

Step S2.4.1: Optionally, if necessary, electroplating is performed on the surface of the plastic package body, and can also be punched above the power semiconductor component as shown in FIG. 11A and FIG. 11B.

Step S2.4.2, optionally, if necessary, punching and electroplating at position of the end pin of the flexible component 4 to form a conductive metal layer and a thermal conduction metal layer.

Step S2.5: removing the plastic package body and the rigid PCB board on the flexible part 3 and other parts without the plastic package body, the same processing is carried out on the upper surface and the lower surface.

FIG. 14B shows a schematic diagram of subsequent steps S3 to S5 of the present embodiment.

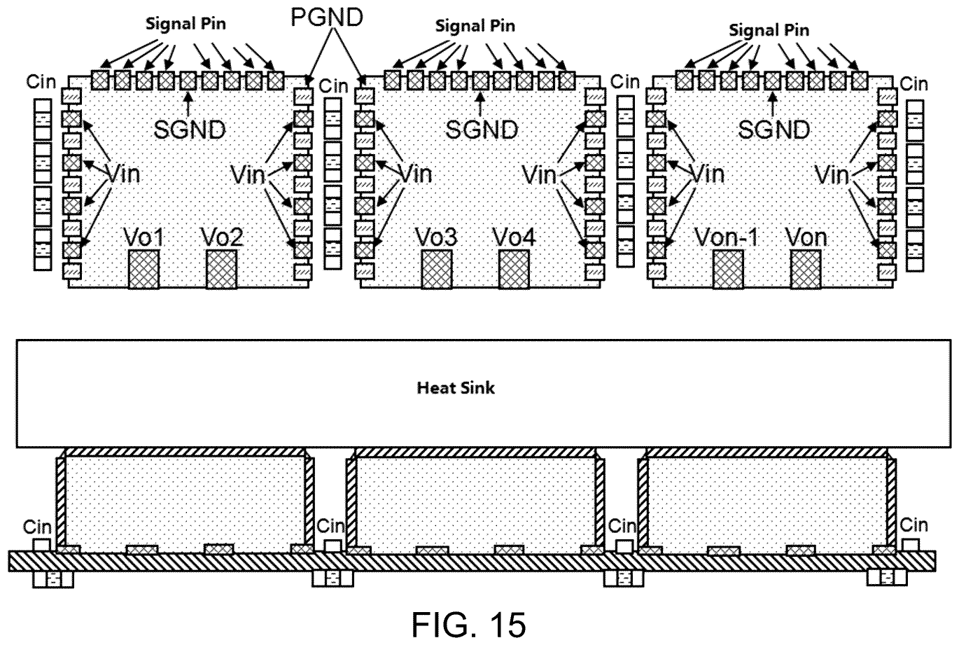

FIG. 15 shows a typical application of a high-frequency high-power-density module power supply module according to the embodiment, and due to the fact that the power semiconductor can be stacked on the magnetic element, the multilateral Pins with low-parasitic inductance can be led out. In order to further improve the system performance, the internal performance basis of the module is provided. Therefore, when the client system is applied, a more accurate implementation mode is also achieved, and the system performance is greatly improved. According to the embodiment, taking a large-current Buck application as an example, a module of integrating two phases Buck is used, a plurality of parallel-connected modules is connected, and finally an N-path effect is obtained. The module sets the input power pins on the left side and the right side of the module and is led out in a staggered mode. The output pins are arranged in the middle of the bottom of the module or close to the lower side, so that big-area copper is laid in parallel and close to the load. The modules are placed in parallel left and right, the input capacitor Cin2 of the client mainboard is arranged between the two modules, and is used to every two adjacent modules at the same time. Due to the fact that the modules are in working phase difference and are multiplexed nearby, the ripple current of Cin2 can be effectively reduced. The Cin2 can be placed on the surface of the same mainboard together with the module at the position of the client mainboard, and can also be arranged on the bottom surface of the mainboard at the adjacent position of the module. The plurality of modules shares one heat sink. Due to the excellent heat dissipation capacity and extremely small loop inductance in the embodiment, high-frequency and high-efficiency high-power long-time operation can be realized.

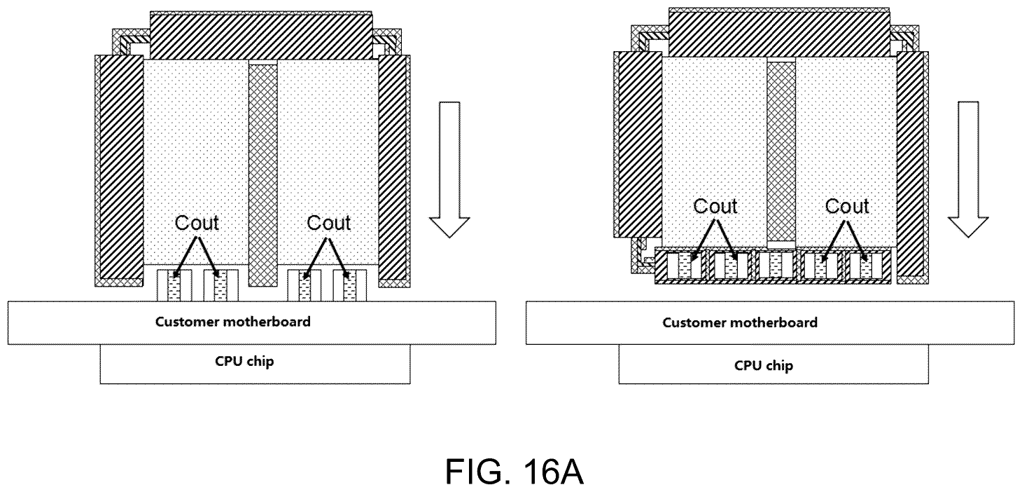

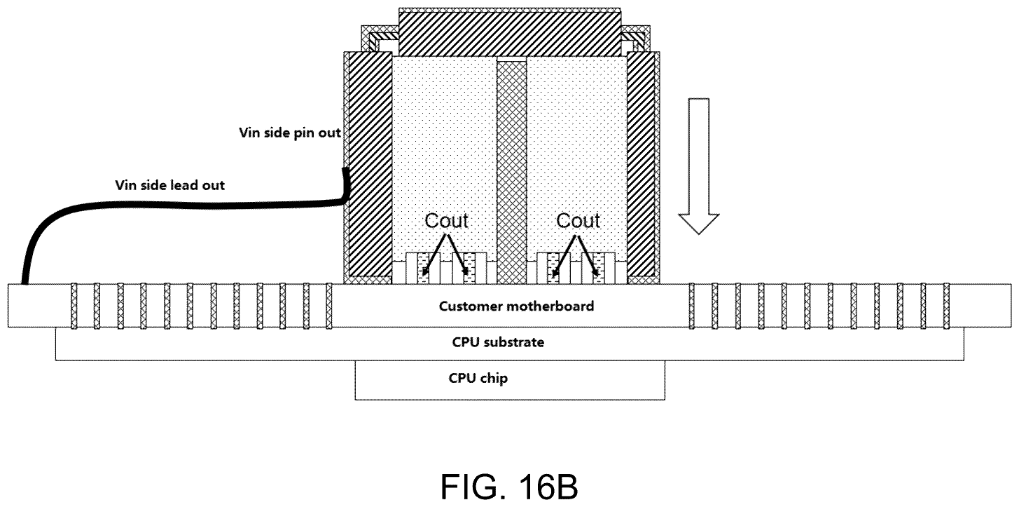

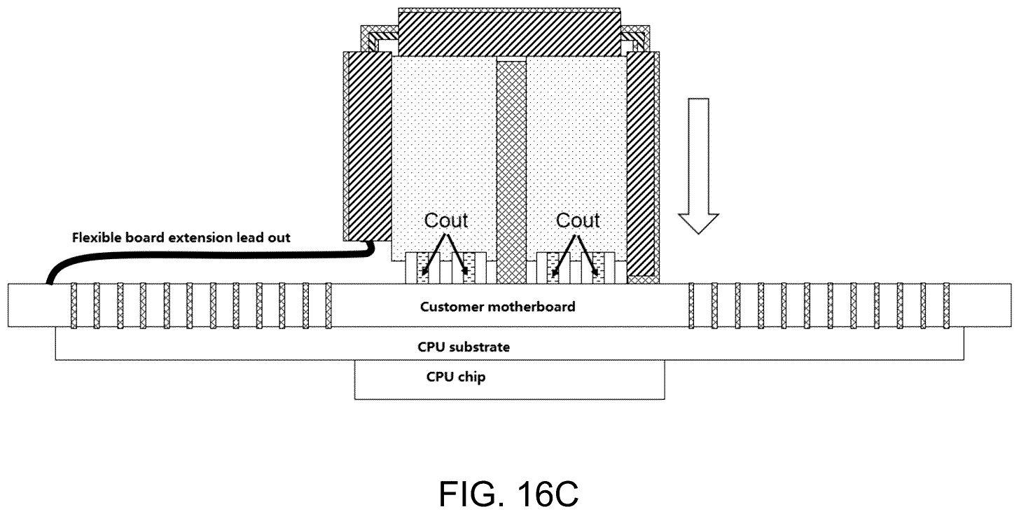

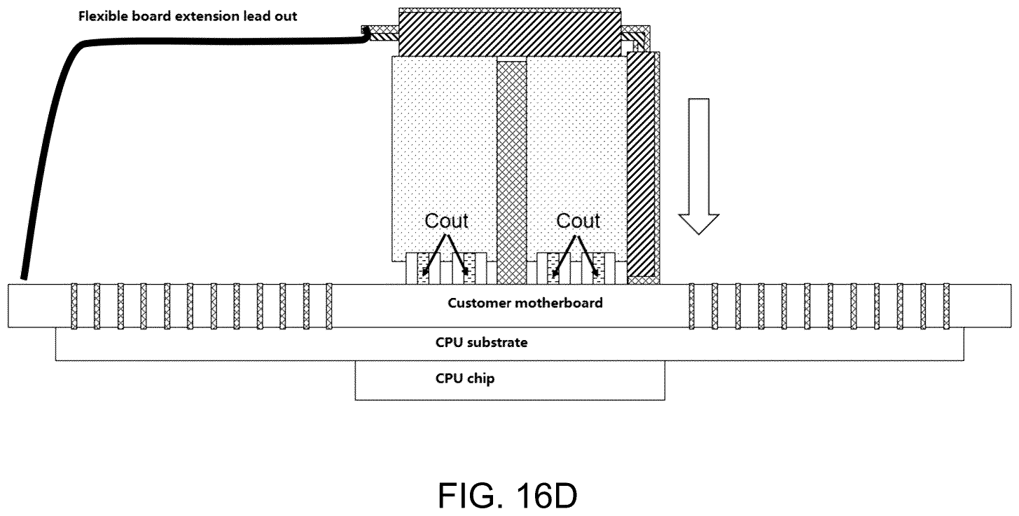

FIG. 16A to FIG. 16D show typical application of a high-frequency high-power-density module power supply module according to the embodiment. In a large-size data processor, such as a CPU/GPU scene, a CPU position perpendicular to a client mainboard is often expected to arrange a large amount of capacitor arrays for power supply decoupling of the CPU. In order to guarantee the number of the capacitors and the arrangement closing to the CPUs, the pins of the module can be lifted, so that the CPU capacitors are arranged below the module, and the requirement is guaranteed.

According to the pin lifting scheme, the pins also occupy a part of area of the client mainboard, the CPU capacitor array can be integrated on the flexible and rigid combination assembly, and the power pins of all modules are led out through the bending mode and arranged at the bottom of the module.

As shown in FIG. 16B, in a preferred embodiment, since there are thousands of pins in the large CPU, the pins are extended to a large area by the CPU substrate outside the CPU wafer area. These positions have via holes of dense hemp and affect the external circuit supply the power to the Vin of Buck.

As shown in FIG. 16C, in a preferred embodiment, a side Vin Pin is led out from the side surface of the carrier element 1, and a customer can introduce power from the side Vin Pin through the power supply flying line.

As shown in FIG. 16D, in a preferred embodiment, the terminal flexible board of the flexible and rigid combination assembly can be extended, and Vin is introduced across the region.

In a large CPU scene, due to the fact that the current is particularly large, multiple phases of Buck are needed, and the phase number can be 10 or even 20, which are jointly together and then output current, but the multi-phase Buck needs to share one controller.

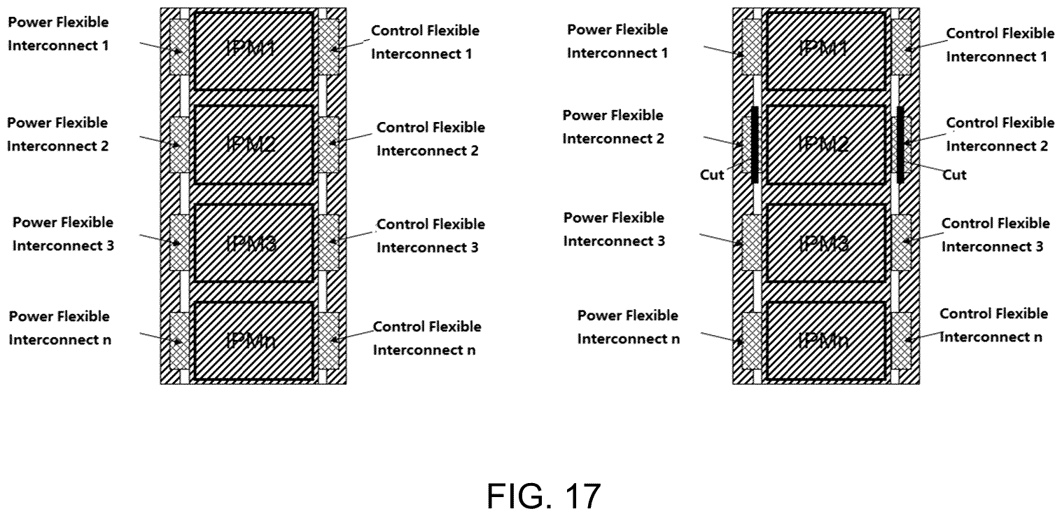

FIG. 17 shows a multi-phase control structure of a high-frequency high-power-density module power supply module according to the embodiment, and on the basis of using the scheme of FIG. 2, multi-phase Buck is integrated in one module. The heat dissipation surface is friendly, the integration degree is high, and the process is simplified (10 times of bending is adjusted to only once). However, such a problem is that the yield is reduced. Therefore, after the test, the yield part of Buck can be cut off, and the part of the module can be used in a derating specification.

What is claimed is:

1. A high-frequency high-power density module power supply, comprising:
a carrier element, at least one surface of the carrier element having a surface power pin;
a flexible and rigid combination assembly, comprising at least one rigid part and at least one flexible part; the at least one rigid part comprises a power semiconductor assembly; the rigid part is electrically connected with the flexible part;
at least one of the flexible and rigid combination assembly is electrically connected to a surface power pin of the carrier element;
the flexible and rigid combination assembly is bent by using the surface of the carrier element as a carrier, and the bending position is the flexible part;
the rigid part and the flexible part are formed by interconnecting the same flexible component, and the at least one rigid part and/or the flexible component are provided with at least one power pin.

2. The high-frequency high-power density module power supply of claim 1, wherein the rigid part containing the power semiconductor assembly is arranged on the upper surface of the carrier element, and the upper surface of the carrier element is in power interconnection with the carrier element.

3. The high-frequency high-power density module power supply of claim 1, wherein the rigid part containing the power semiconductor assembly is arranged on the side surface of the carrier element, and power interconnection is carried out with the carrier element on the side surface of the carrier element.

4. The high-frequency high-power density module power supply of claim 1, wherein at least two rigid parts comprise power semiconductor components and are respectively arranged on two different side surfaces of the carrier element.

5. The high-frequency high-power density module power supply of claim 1, wherein the rigid part containing the power semiconductor assembly is arranged on the lower surface of the carrier element, and power interconnection is carried out with the carrier element on the lower surface of the carrier element.

6. The high-frequency high-power density module power supply of claim 1, wherein the flexible component comprises at least one insulating layer and at least two conductive layers separated by the insulating layer, the flexible component comprises at least one overlapping region, and in the overlapping region, both sides of the insulating layer are provided with conductive layers, and the polarities of the electrodes of the conductive layer are opposite.

7. The high-frequency high-power density module power supply of claim 1, wherein the flexible component is provided with at least one power pin, specifically, an end pin is arranged at the end of the flexible component, and the end pin comprises at least one power pin.

8. The high-frequency high-power density module power supply of claim 7, wherein the end pin is formed on one surface of the carrier element after being bent through the flexible component.

9. The high-frequency high-power density module power supply of claim 8, wherein a space for accommodating the end pin is formed in one surface of the carrier element.

10. The high-frequency high-power density module power supply of claim 1, wherein the rigid part and/or the flexible part are provided with at least one power grounding pin, and the power pin and the power grounding pin are alternately arranged.

11. The high-frequency high-power density module power supply of claim 6, wherein a conductive layer arranged on one side, which is in the direction away from the carrier element, of the flexible component is an outer conductive layer, and other conductive layers not including the outer conductive layer are inner conductive layers;
the flexible component is provided with at least one power pin, and specifically, an end pin is arranged at the end of the flexible component, and the end pin comprises at least one power pin;
the inner conductive layer is electrically connected to at least one end pin by penetrating through the flexible component.

12. The high-frequency high-power density module power supply of claim 1, wherein the rigid part and/or the flexible part are provided with at least one signal pin, and the signal pin and the power pin are respectively arranged on different surfaces of the carrier element.

13. The high-frequency high-power density module power supply of claim 1, wherein the flexible component has a copper reduction structure or a copper removal structure to form a flexible part.

14. The high-frequency high-power density module power supply of claim 13, wherein the copper reduction structure is of a thinned structure or a stamp hole structure.

15. The high-frequency high-power density module power supply of claim 1, wherein the power semiconductor assembly comprises a power semiconductor element and a first plastic package body which are arranged on the upper surface of the flexible component, the power semiconductor element is electrically connected with the flexible component, and the first plastic package body wraps the power semiconductor element and at least one part of the upper surface of the flexible component.

16. The high-frequency high-power density module power supply of claim 1, wherein the power semiconductor assembly comprises a first PCB board arranged on the upper surface of the flexible component, a power semiconductor element arranged on the first PCB board and a first plastic package body, the power semiconductor element is electrically connected with the flexible component through the first PCB board, and the first plastic package body wraps the first PCB board and the power semiconductor element.

17. The high-frequency high-power density module power supply of claim 16, wherein the power semiconductor assembly further comprises a second PCB arranged on the lower surface of the flexible part, and the first PCB is electrically connected with the second PCB through a via hole electrical connector arranged in the via hole.

18. The high-frequency high-power density module power supply of claim 16, wherein the power semiconductor assembly further comprises at least one embedded wafer, the embedded wafer is arranged in the first PCB and/or between the first PCB and the flexible component and/or the inner of the flexible PCB, and the embedded wafer is electrically connected with the first PCB and/or the flexible component.

19. The high-frequency high-power density module power supply of claim 1, wherein the rigid part comprises a side capacitor arranged on the flexible component.

20. The high-frequency high-power density module power supply of claim 19, wherein the rigid part further comprises a second plastic package body, and the second plastic package body wraps the side capacitor and at least part of the flexible component.

21. The high-frequency high-power density module power supply of claim 19, wherein an outer conductive layer on at least one side of the flexible component is provided with a first electrical area and a second electrical area which are opposite in electrical property, the second electrical area is electrically connected with the corresponding inner conductive layer, at least one side capacitor is arranged on the outer conductive layer, and two electrodes of the side capacitor are electrically connected with the first electrical area and the second electrical area respectively.

22. The high-frequency high-power density module power supply of claim 1, wherein the rigid part comprises a thickened metal block, and the thickened metal block is electrically connected with the flexible component.

23. The high-frequency high-power density module power supply of claim 15, wherein the circuit formed by the power semiconductor element comprises at least two switch bridge arms, and the high-frequency jump voltage ends of the switch bridge arms are electrically interconnected by means of electrical connectors provided on the surface of the carrier element.

24. The high-frequency high-power density module power supply of claim 15, wherein a circuit formed by the power semiconductor element comprises at least one switch bridge arm, and a direct-current voltage end of the switch bridge arm is electrically connected with the flexible component through an electrical connector arranged on the surface of the carrier element.

25. The high-frequency high-power density module power supply of claim 1, wherein at least one rigid part is a rigid capacitor assembly;
when the flexible component is assembled on the surface of the carrier element, the outer conductive layer on at least one side of the flexible component is provided with a first electrical area and a second electrical area which are opposite in electrical property, and the second electrical area is electrically connected with the inner conductive layer at the corresponding position;
the rigid capacitor assembly is arranged on the conductive layer on the outer side of the flexible component, the rigid capacitor assembly comprises a third plastic package body and at least one side capacitor, the two electrodes of the side capacitor are electrically connected with the first electrical area and the second electrical area respectively, and the third plastic package body wraps the side capacitor and at least one part of the conductive layer on the outer side of the flexible component.

26. The high-frequency high-power density module power supply of claim 25, wherein the bottom of the rigid capacitor assembly is flush with the bottom of the carrier element; and the at least one rigid part is provided with at least one power pin, specifically, the bottom of the rigid capacitor assembly is provided with at least one power pin through electroplating.

27. The high-frequency high-power density module power supply of claim 25, wherein at least one rigid part is a rigid control assembly;
when the flexible component is assembled on the surface of the carrier element, the rigid control assembly is arranged on the conductive layer on the outer side of the flexible component on at least one side;
the rigid control assembly comprises a control chip and a fourth plastic package, the fourth plastic package covers the control chip and at least a part of the conductive layer outside the flexible component, and the control chip is used for providing a control signal to the power semiconductor component.

28. The high-frequency high-power density module power supply of claim 27, wherein the bottom of the rigid control assembly and the bottom of the rigid capacitor assembly are flush with the bottom of the carrier element, and at least one signal pin is arranged at the bottom of the rigid control assembly through electroplating; and the at least one rigid part is provided with at least one power pin, and specifically, the bottom of the rigid capacitor assembly is provided with at least one power pin through electroplating.

29. The high-frequency high-power density module power supply of claim 25, wherein the bottom of at least one rigid part is lower than the bottom of the carrier element, so that when the high-frequency high-power density module power supply is installed on the client mainboard, the space for accommodating the output decoupling capacitor is reserved below the carrier element.

30. The high-frequency high-power density module power supply of claim 25, wherein at least one rigid part is an output decoupling capacitor assembly, the output decoupling capacitor assembly is arranged at the bottom of the carrier element, the output decoupling capacitor assembly is used for containing an output decoupling capacitor, one electrode of the decoupling capacitor is electrically connected with the carrier element, and the other electrode is electrically connected with the flexible component.

31. The high-frequency high-power density module power supply of claim 1, further comprises a power supply flying wire, one end of the power supply flying wire is electrically connected with the flexible and rigid combination assembly, the other end of the power supply flying wire is used for being electrically connected with a client mainboard, and the power supply flying wire is used for supplying power to a high-frequency high-power density module power supply from the position away from the high-frequency high-power density module power supply.

32. A flexible and rigid combination assembly according to claim 1.

33. A high-frequency high-power density module power supply, comprising:
at least one power semiconductor assembly, wherein the power semiconductor assembly comprises a power semiconductor element and a first plastic package body, and the first plastic package body wraps the power semiconductor element;
a carrier element arranged at the bottom of the high-frequency high-power density module power supply, wherein the power semiconductor assembly is arranged above the carrier element, and the carrier element is electrically connected with the power semiconductor assembly;
a bottom pin, the bottom pin being arranged at the bottom of a high-frequency high-power density module power supply;
an electrical connection assembly, the electrical connection assembly being used for electrically connecting the power semiconductor assembly to a bottom pin;
the top of the power semiconductor assembly is provided with a top heat dissipation structure;
the top heat dissipation structure comprises a top heat dissipation coating and a thermal connector, and the top heat dissipation coating is arranged on the upper surface of the first plastic packaging body through electroplating;
the thermal connector is disposed inside the first plastic package body, and the thermal connector thermally connects the at least one power semiconductor element with the top heat dissipation plating layer.

34. The high-frequency high-power density module power supply of claim 33, wherein the electrical connection assembly is a flexible component, the flexible component is disposed on at least one side surface of the carrier element, the flexible component comprises at least one insulating layer and at least two conductive layers separated by the insulating layer, the flexible component at least comprises an overlapping region, and both sides of the insulating layer in the overlapping region have conductive layers and the electrodes of the conductive layer are opposite.

35. The high-frequency high-power density module power supply of claim 34, wherein a side rigid part is arranged on the flexible component, and the side surface of the rigid part comprises at least one of a rigid capacitor assembly and a rigid control assembly;
the rigid capacitor assembly comprises a third plastic package body and at least one side capacitor, the two electrodes of the side capacitor are electrically connected with different conductive layers of the flexible component respectively, and the third plastic package body wraps the side capacitor and at least one part of the conductive layer on the outer side of the flexible component;
the rigid control assembly comprises a control chip and a fourth plastic package, the fourth plastic package covers the control chip and at least a part of the conductive layer outside the flexible component, and the control chip is used for providing a control signal to the power semiconductor component.

36. The high-frequency high-power density module power supply of claim 35, wherein the outer side of at least one side rigid part is provided with a side metal plating layer by means of electroplating.

37. A parallel high-frequency high-power density module power supply combination, comprising:
at least two high-power density module power supplies, a bottom pin is arranged on the bottom surface of the high-frequency high-power density module power supply, the bottom pin comprises a signal pin, an input power pin, an output power pin and a power grounding pin, the bottom surface is provided with a first edge, a second edge, a third edge and a fourth edge, the second edge is opposite to the fourth edge; the input power pin and the power grounding pin are alternately arranged on the second edge or the fourth edge of the bottom surface in an array;
the high-frequency high-power density module power supply is arranged in parallel, so that the second edge of one high-frequency high-power density module power supply is close to the fourth edge of the other high-frequency high-power density module power supply.

38. The parallel high-frequency high-power density module power supply combination of claim 37, wherein a common radiator is arranged at the top of the parallel high-frequency high-power density module power supply combination.

39. The parallel high-frequency high-power density module power supply combination of claim 37, further comprising:
a flexible and rigid combination assembly, comprising at least one rigid part and at least one flexible part; the at least one rigid part comprises a power semiconductor assembly; the rigid part and the flexible part are connected through a same flexible component, the rigid part is electrical connected with the bottom pin through the flexible component;
a carrier element, the rigid part is disposed on a surface of the carrier element; the flexible component wraps the top surface, at least a side surface of the carrier element and extends to the bottom of the carrier element, the bending position of the flexible component is the flexible part, the carrier element is electrical connected with the power semiconductor assembly;
the flexible component comprises at least one insulating layer and at least two conductive layers separated by the insulating layer, the flexible component comprises at least one overlapping region, and in the overlapping region, both sides of the insulating layer are provided with conductive layers, and the polarities of the electrodes of the conductive layer are opposite.

40. The parallel high-frequency high-power density module power supply combination of claim 37, wherein the bottom pin comprises an output pin,
the first edge and the third edge are parallel, the output pin is arranged at the first edge or is not arranged on the bottom surface, and the signal pin array is arranged at the third edge;
the outer side of the second edge and the outer side of the fourth edge of the high-frequency high-power density module power supply are each provided with a client mainboard input capacitor, and the two electrodes of the client mainboard input capacitor are electrically connected with the input power pin and the power grounding pin respectively; and
the common customer mainboard input capacitor is shared between every two adjacent high-frequency high-power density module power supplies;
one electrode of the shared client mainboard input capacitor is electrically connected with the input power pins at the corresponding positions of the two adjacent high-frequency high-power density module power supplies, and the other electrode is electrically connected with the power grounding pins at the corresponding positions of the two adjacent high-frequency high-power density module power supplies.

41. A method for manufacturing a high-frequency high-power density module power supply according to claim 1, comprising:
providing a carrier element;
a pre-formed flexible and rigid combination assembly;
glue and solder are arranged on the surface of the carrier element, the glue is used for fixedly connecting the carrier element with the flexible and rigid combination assembly, and the solder is used for electrically connecting the carrier element with the flexible and rigid combination assembly;
the power semiconductor component is arranged on the upper surface of the carrier element, the flexible component is bent and extends to the bottom along the upper surface of the carrier element, and at least one side surface of the flexible component extends to the bottom, and the bending position of the flexible component is a flexible part;
performing high-temperature treatment, melting and welding the solder, and curing and bonding the glue;
the pre-formed flexible and rigid combination assembly is specifically:
providing a flexible component;
an electronic component required for the rigid part is provided on the flexible component or on the flexible component and inside the flexible component.

42. The method for manufacturing the high-frequency high-power-density module power supply of claim 41, wherein after the electronic elements required by the rigid part are arranged on the flexible component or on the flexible component and in the flexible component, partially plastic packaging is carried out, and a rigid part is formed on the flexible component.

43. A manufacturing method of the high-frequency high-power density module power supply of claim 15, comprising the following steps:
providing a carrier element;
a pre-formed flexible and rigid combination assembly, wherein the step S2 is specifically as follows:
providing a multi-layer PCB, at least one layer of the multi-layer PCB being a flexible PCB, and at least one layer being a rigid PCB;
removing part of the rigid PCB, and exposing the flexible PCB as a flexible part;
providing an electronic component on the multi-layer PCB or on the multi-layer PCB and in the multi-layer PCB board;
performing plastic packaging to obtain a pre-plastic package body;
removing part of the pre-plastic package to form a rigid part;
glue and solder are arranged on the surface of the carrier element, the glue is used for fixedly connecting the carrier element with the flexibly and rigid combination assembly, and the solder is used for electrically connecting the carrier element with the flexible and rigid combination assembly;
the power semiconductor component is arranged on the upper surface of the carrier element, the flexible component is bent and extends to the bottom along the upper surface and at least one side surface of the flexible component, and the bending position of the flexible component is a flexible part;
performing high-temperature treatment, melting and welding the solder, and curing and bonding the glue.

44. The manufacturing method of the high-frequency high-power density module power supply of claim 43, wherein the flexible and rigid combination assembly comprises a plurality of sets of flexible and rigid combination sub-assemblies which are connected in parallel and achieve the same function, and each set of flexible and rigid combination sub-assemblies comprises a rigid part, a flexible part, a flexible component and an end pin; testing each group of flexible and rigid combination sub-assemblies after high-temperature treatment, and cutting the flexible components corresponding to the flexible and rigid combination sub-assemblies to disconnect the flexible components corresponding to the flexible and rigid combination sub-assemblies.

45. A method for manufacturing a high-frequency high-power density module power supply according to claim 33, comprising:
providing a carrier element;
a pre-formed flexible and rigid combination assembly;
glue and solder are arranged on the surface of the carrier element, the glue is used for fixedly connecting the carrier element with the flexible and rigid combination assembly, and the solder is used for electrically connecting the carrier element with the flexible and rigid combination assembly;
the power semiconductor component is arranged on the upper surface of the carrier element, the flexible component is bent and extends to the bottom along the upper surface and at least one side surface of the flexible component, and the bending position of the flexible component is a flexible part;
performing high-temperature treatment, melting and welding the solder, and curing and bonding the glue;
the pre-formed flexible and rigid combination assembly is specifically:
providing a multi-layer PCB, at least one layer of the multi-layer PCB being a flexible PCB, and at least one layer being a rigid PCB;
removing part of the rigid PCB, and exposing the flexible PCB as a flexible part;
providing an electronical component on the multi-layer PCB or on the multi-layer PCB and in the multi-layer PCB;
performing plastic packaging to obtain a pre-plastic package body;
punching holes in the upper portion of the pre-plastic package body, and electroplating the upper surface of the pre-plastic package body;
a portion of the pre-plastic package body is removed to form a rigid part.

46. A high-frequency high-power density module power supply, comprising:
a bottom pin, the bottom pin being arranged at the bottom of a high-frequency high-power density module power supply;
a carrier element, wherein at least one surface of the carrier element is provided with a surface power pin; the carrier element is arranged above the bottom pin;
at least one rigid part, wherein the rigid part comprises at least one power semiconductor assembly, the rigid part is provided with at least one power pin, the rigid part is electrically connected with the surface power pin, and the rigid part is arranged on the side surface of the carrier element.

47. The high-frequency high-power density module power supply of claim 46, wherein at least one side surface of the carrier element is provided with the surface power pin and is provided with the rigid part, and the power pin and the surface power pin of the rigid part are electrically connected nearby.

48. The high-frequency high-power density module power supply of claim 46, wherein the carrier element comprises an electrical conductor, and at least a part of the electrical conductor is parallel to the bottom of the high-frequency high-power density module power supply.

49. The high-frequency high-power density module power supply of claim 48, wherein the carrier element comprises an integrated inductor, the integrated inductor comprises at least two windings, and the electrical conductor is a part of the winding.

50. The high-frequency high-power density module power supply of claim 49, wherein one end of the winding is located on the side surface of the carrier element, and the other end of the winding is located on the bottom face of the carrier element.

51. The high-frequency high-power density module power supply of claim 46, wherein the carrier element comprises at least one of a transformer, a capacitor combination, and a sub-power supply module.

52. The high-frequency high-power density module power supply of claim 46, wherein at least two rigid parts are arranged; the rigid parts are arranged on different side surfaces of the carrier element respectively; and each rigid part comprises at least one power semiconductor assembly.

53. The high-frequency high-power density module power supply of claim 46, wherein at least two rigid parts are electrically connected through a flexible part; and at least one part of the flexible part is arranged on the upper surface of the carrier element.

54. The high-frequency high-power density module power supply of claim 53, wherein the flexible part is provided with an electronic element.
